(19) United States
(12) Patent Application Publication
(10) Pub. No.: US 2025/0330731 A1
(43) Pub. Date: Oct. 23, 2025

(54) IMAGE SENSOR AND OPERATING METHOD OF IMAGE SENSOR

(71) Applicant: Samsung Electronics Co., Ltd., Suwon-si (KR)

(72) Inventors: Dongjin PARK, Suwon-si (KR); Wooseok Choi, Suwon-si (KR); Jeehong Lee, Suwon-si (KR); Sunghyuk Yim, Suwon-si (KR)

(73) Assignee: Samsung Electronics Co., Ltd., Suwon-si (KR)

(21) Appl. No.: 19/027,169

(22) Filed: Jan. 17, 2025

(30) Foreign Application Priority Data
Apr. 19, 2024 (KR) 10-2024-0052816

(51) Int. Cl. H04N 25/78; H04N 25/77

(52) U.S. Cl. CPC H04N 25/78; H04N 25/77

(57) ABSTRACT

An image sensor is provided. The image sensor includes: a first pixel group including first pixels, wherein first micro lenses are on the first pixels, respectively; a second pixel group including second pixels, wherein a second micro lens is on at least two of the second pixels; and a timing controller configured to: control, in a first sensing readout period of a readout period, a first image signal generated from each of the first pixels and a second image signal generated from a first portion of the second pixels to be output, and control, in a second sensing readout period of the readout period that follows the first sensing readout period, a third image signal generated from each of the first pixels and a fourth image signal generated from each of the second pixels to be output.

### CROSS-REFERENCE TO RELATED APPLICATION

This application is based on and claims priority to Korean Patent Application No. 10-2024-0052816, filed on Apr. 19, 2024, in the Korean Intellectual Property Office, the disclosure of which is incorporated by reference herein in its entirety.

### BACKGROUND

The present disclosure relates to an image sensor, and more specifically, to an image sensor including normal pixels and autofocus pixels, and a readout method of the image sensor.

An image sensor is a device that captures a two-dimensional or three-dimensional image of an object. An image sensor generates image data of an object by using a photoelectric conversion element that reacts according to the intensity of light reflected from or emitted by the object.

Recently, autofocusing (AF), which automatically detects the focus of the image sensor, has been widely used. In particular, various studies are being conducted on phase difference autofocusing technology due to its fast focus detection speed. For example, in phase difference autofocusing, a focal length may be adjusted by automatically driving a focusing lens such that light passing through an image capturing lens is divided and detected at different locations and detection signals have the same intensity at the same phase.

For image sensors including normal pixels and autofocusing pixels, technology is required to improve image quality while performing an autofocus detection operation.

### SUMMARY

One or more embodiments provide an image sensor for improving image quality by reading out a second image signal generated from some second pixels of a second pixel group when reading out a first image signal generated from first pixels and reading out a fourth image signal generated from all second pixels of a second pixel group when reading out a third image signal generated from the first pixels, and an image processing device.

According to an aspect of an embodiment, an image sensor includes: a first pixel group including a plurality of first pixels, wherein a plurality of first micro lenses are on the plurality of first pixels, respectively; a second pixel group including a plurality of second pixels, wherein a second micro lens is on at least two of the plurality of second pixels; and a timing controller configured to: control, in a first sensing readout period of a readout period, a first image signal generated from each of the plurality of first pixels and a second image signal generated from a first portion of the plurality of second pixels to be output, and control, in a second sensing readout period of the readout period that follows the first sensing readout period, a third image signal generated from each of the plurality of first pixels and a fourth image signal generated from each of the plurality of second pixels to be output.

According to another aspect of an embodiment, an image sensor includes: a first pixel group including a plurality of first pixels arranged in rows and columns; a second pixel group including a plurality of second pixels arranged in rows and columns; a plurality of first micro lenses on the plurality of first pixels, respectively; a second micro lens on at least two of the plurality of second pixels, the second micro lens having a diameter greater than that of a first micro lens of the plurality of first micro lenses; and a readout circuit configured to: sequentially output, in a readout period, a first pixel value generated based on each of the plurality of first pixels and a third pixel value generated based on each of the plurality of first pixels, and sequentially output, in the readout period, a second pixel value generated based on a first portion of the plurality of second pixels among the plurality of second pixels and a fourth pixel value generated based on each of the plurality of second pixels.

According to another aspect of an embodiment, an operating method of an image sensor including a first pixel group with first pixels, a second pixel group with second pixels, first micro lenses disposed on the first pixels, respectively, and a second micro lens disposed on at least two of the second pixels, is provided. The operating method includes: outputting a first reset signal for the first pixels and a second reset signal for the second pixels; outputting a first image signal generated from each of the first pixels and a second image signal generated from a first portion of the second pixels; and outputting a third image signal generated from the of the first pixels and a fourth image signal from each of the second pixels.

### BRIEF DESCRIPTION OF DRAWINGS

The above and other aspects and features will be more apparent from the following description of embodiments, taken in conjunction with the accompanying drawings, in which:

FIG. 1 is a diagram illustrating a structure of a digital imaging device according to an embodiment;

FIG. 2 is a block diagram illustrating an image sensor according to an embodiment;

FIG. 3 is a diagram illustrating a pixel array according to an embodiment;

FIG. 4 is a diagram for describing an image signal according to an embodiment;

FIG. 5A is a diagram illustrating a pixel array according to an embodiment;

FIG. 5B is a diagram illustrating a pixel array according to an embodiment;

FIG. 5C is a diagram illustrating a pixel array according to an embodiment;

FIG. 6 is a circuit diagram of a pixel included in the pixel array of FIG. 2;

FIG. 7 is a circuit diagram of a pixel included in an image sensor according to an embodiment;

FIG. 8 is a timing diagram of an image sensor for reading a pixel signal, according to an embodiment;

FIG. 9 is a flowchart of a method of operating an image sensor, according to an embodiment;

FIG. 10 is a circuit diagram illustrating an implementation example of a pixel according to an embodiment;

FIG. 11 is a timing diagram of an image sensor for reading a pixel signal, according to an embodiment;

FIG. 12 is a diagram for describing an image signal of a first pixel group, according to an embodiment; and

FIG. 13 is a block diagram illustrating an electronic device according to an embodiment.

### DETAILED DESCRIPTION

Hereinafter, embodiments will be described in detail with reference to the attached drawings. In the drawings, like elements are labeled like reference numerals and repeated description thereof will be omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each embodiment provided in the following description is not excluded from being associated with one or more features of another example or another embodiment also provided herein or not provided herein but consistent with the present disclosure.

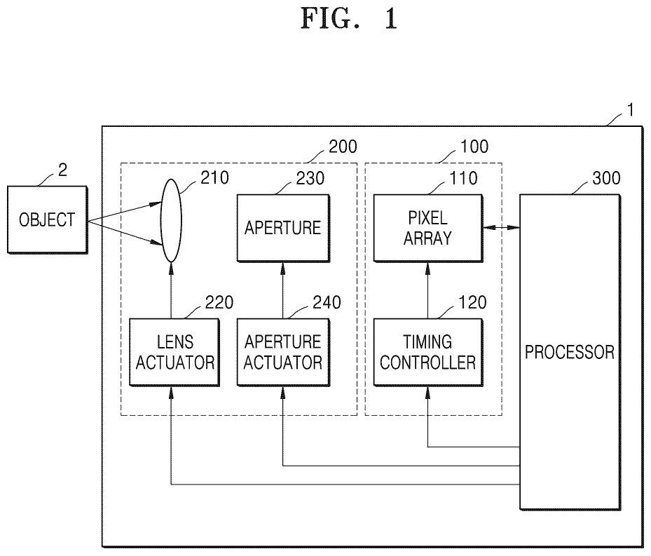

FIG. 1 is a diagram illustrating a structure of a digital imaging device according to an embodiment. A digital imaging device 1 may perform an auto focusing (AF) function of automatically detecting a focus.

The digital imaging device 1 according to an embodiment may include an imaging unit (i.e., imaging device) 200, an image sensor 100, and a processor 300. The digital imaging device 1 may have a focus detection function. The digital imaging device 1 may be an electronic device with image or light sensing functions. For example, the electronic device may be any one of a camera, a smartphone, a wearable device, an Internet of Things (IoT), a tablet personal computer (PC), a personal digital assistant (PDA), a portable multimedia player (PMP), and a navigation device. For example, an electronic device may be a device that is provided as a portion of a vehicle, furniture, manufacturing equipment, door, or various measuring devices.

Operations of the digital imaging device 1 may be controlled by the processor 300. The processor 300 may provide control signals for operation of each component, such as a lens actuator 220, an aperture actuator 240, and a timing controller 120.

The imaging unit 200 is a component that receives light and may include a lens 210, the lens actuator 220, an aperture 230, and the aperture actuator 240. The lens 210 may include a plurality of lenses.

The lens actuator 220 may communicate information about focus detection with the processor 300 and adjust a position of the lens 210 according to a control signal provided from the processor 300. The lens actuator 220 may move the lens 210 in a direction in which a distance from an object 2 increases or decreases. Accordingly, the distance between the lens 210 and the object 2 may be adjusted. The object 2 may be in focus or blurred according to the position of the lens 210.

For example, if the distance between the lens 210 and the object 2 is relatively close, the lens 210 may be out of an in-focus position for focusing on the object 2, and there may be a phase difference between images captured by the image sensor 100. The lens actuator 220 may move, based on a control signal provided from the processor 300, the lens 210 in a direction in which the distance from the object 2 increases.

Alternatively, when the distance between the lens 210 and the object 2 is relatively long, the lens 210 may be out of focus, and there may be a phase difference between images formed on the image sensor 100. The lens actuator 220 may move, based on a control signal provided from the processor 300, the lens 210 in a direction in which the distance from the object 2 decreases.

The image sensor 100 may convert incident light into an image signal. The image sensor 100 may include a pixel array 110 and a timing controller 120. An optical signal passing through the lens 210 and the aperture 230 may reach a light-receiving surface of the pixel array 110 to form an image of a subject.

The pixel array 110 may be a complementary metal oxide semiconductor image sensor (CIS) that converts optical signals into electrical signals. The sensitivity of the pixel array 110, or the like, may be adjusted by the timing controller 120. The pixel array 110 may include a plurality of pixels that convert optical signals into electrical signals. A plurality of pixels may generate pixel signals according to intensity of each piece of sensed light. The pixel array 110 may include pixels to perform an AF function or a distance measurement function. As an example, some of the plurality of pixels included in the pixel array 110 may be AF pixels for performing an AF function, and some of the remaining pixels may be normal pixels that generate image signals. For example, 50% of the plurality of pixels included in the pixel array 110 may be AF pixels, and the remaining 50% may be normal pixels. However, embodiments are not limited thereto.

The image sensor 100 may include a micro lens array disposed on the pixel array 110. The micro lens array may include micro lenses corresponding to the plurality of pixels included in the pixel array 110. The micro lens array may include micro lenses corresponding to AF pixels and micro lenses corresponding to normal pixels.

The image sensor 100 may generate image data by using normal pixels and AF pixels. Image data may include frame-by-frame images and/or AF data. For example, the image sensor 100 may generate AF data using AF pixels. The image sensor 100 may generate signal-to-noise ratio (SNR) image data to improve an SNR by using normal pixels. The image sensor 100 may generate high dynamic range (HDR) image data for generating an HDR image by using normal pixels.

The timing controller 120 may control the overall operation of the image sensor 100. The timing controller 120 may control the operation of components included in the image sensor 100. The timing controller 120 may control the operation of pixels included in the pixel array 110. For example, the timing controller 120 may generate a plurality of control signals to control the operation of pixels included in the pixel array 110.

The image sensor 100 may provide image data to the processor 300. The image data may include frame-by-frame images and/or AF data. The processor 300 may perform phase difference calculation for the AF function using AF data. In an embodiment, the processor 300 may perform a phase difference calculation based on a phase detection signal included in AF data. The processor 300 may process image data output from the image sensor 100. The processor 300 may obtain a position of a focus, a direction of the focus, or a distance between the object 2 and the image sensor 100, as a result of the phase difference calculation. The processor 300 may output a control signal to the lens actuator 220 to move the position of the lens 210 based on the result of the phase difference calculation.

In an embodiment, the processor 300 may generate an image with an improved SNR by using image data. The processor 300 may receive SNR image data to improve the SNR and generate an image with an improved SNR based on the SNR image data.

In an embodiment, the processor 300 may generate an HDR image by using image data. The processor 300 may receive HDR image data for generating an HDR image and generate an HDR image based on the HDR image data.

The processor 300 may perform image signal processing for improving image quality, such as reducing noise of an input signal, performing gamma correction, color filter array interpolation, color matrix, color correction, and color enhancement. Additionally, image data generated by image signal processing to improve image quality may be compressed to generate an image file, or image data may be restored from the image file.

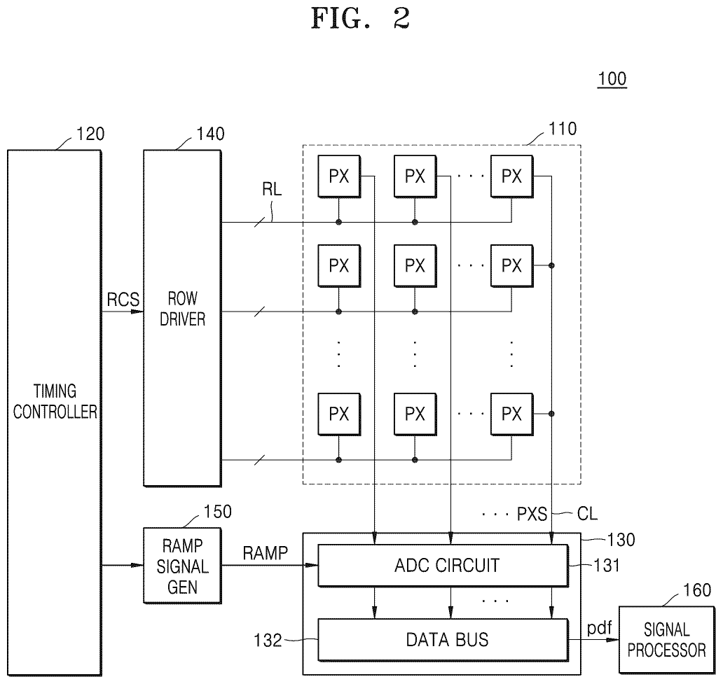

FIG. 2 is a block diagram illustrating an image sensor according to an embodiment.

Referring to FIG. 2, the image sensor 100 may include a pixel array 110, a timing controller 120, a readout circuit 130, and a row driver 140. The readout circuit 130 may include an analog-to-digital conversion (ADC) circuit 131 and a data bus 132. In an embodiment, the pixel array 110, the row driver 140, the readout circuit 130, a ramp signal generator 150, the timing controller 120, and a signal processor 160 may be implemented as a single semiconductor chip or semiconductor module. In an embodiment, the pixel array 110, the row driver 140, the readout circuit 130, the ramp signal generator 150, and the timing controller 120 may be implemented as a single semiconductor chip or semiconductor module, and the signal processor 160 may be implemented as another semiconductor chip or semiconductor module.

The pixel array 110 may be connected to a plurality of row lines RL and a plurality of column lines CL, and may include a plurality of pixels PX arranged in rows and columns. The pixel array 110 may include a plurality of pixels PX that sense light of different wavelengths from each other. Arrangement of the pixels PX may be implemented in various ways. In an embodiment, the pixel array 110 may include normal pixels and AF pixels.

Each of the plurality of pixels PX may include at least one photoelectric conversion element. A pixel PX may detect light using a photoelectric conversion element and output an image signal, which is an electrical signal according to the detected light. For example, the photoelectric conversion element may include a light sensing element including an organic material or an inorganic material, such as an inorganic photodiode, an organic photodiode, a perovskite photodiode, a photo transistor, a photo gate, or a pinned photodiode. For example, each of the plurality of pixels PX may include one photoelectric conversion element. However, embodiments are not limited thereto, and each of the plurality of pixels PX may include a plurality of photoelectric conversion elements, and some pixels of the plurality of pixels PX may include a plurality of photoelectric conversion elements, and other pixels thereof may include one photoelectric conversion element.

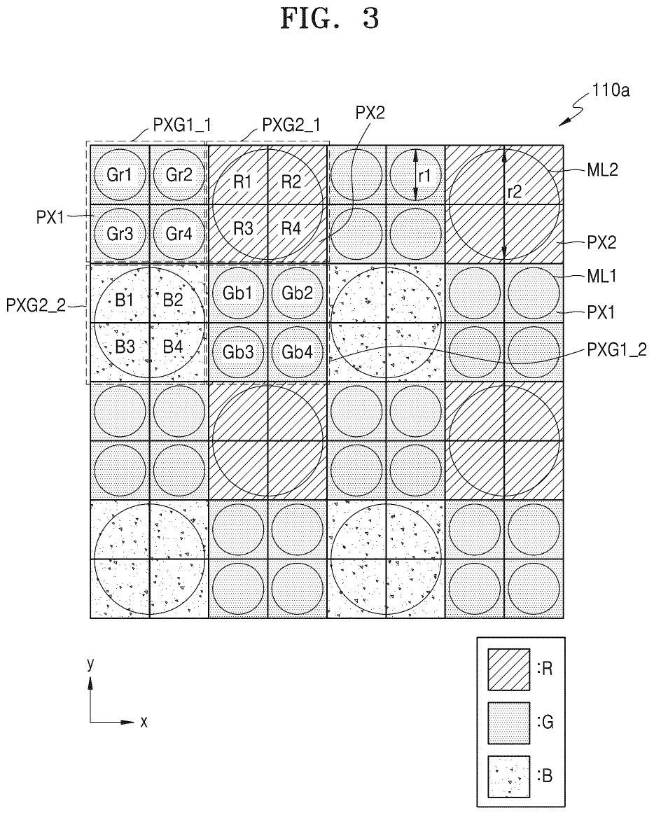

A micro lens for light focusing (for example, a first micro lens ML1 and a second micro lens ML2 in FIG. 3) may be arranged on each of the plurality of pixels PX or on each of pixels including adjacent pixels PX. As an example, micro lenses respectively corresponding to some pixels PX among pixels included in the pixel array 110 may be respectively arranged on some pixels PX. Micro lenses corresponding to pixel groups may be respectively disposed on some pixel groups among pixel groups including adjacent pixels PX in the pixel array 110. The pixels PX may detect light in a certain spectral region from light received through micro lenses arranged thereon.

The pixel array 110 may include a first pixel group and a second pixel group. The pixel array 110 may include a structure in which first pixel groups and second pixel groups are alternately and repeatedly arranged in rows and columns. The first pixel group may include a plurality of first pixels. A first micro lens may be disposed on each of the first pixels. First micro lenses respectively corresponding to the first pixels may be respectively disposed on the first pixels included in the first pixel group.

For example, the first pixel group may include four first pixels arranged 2×2. A first micro lenses may be disposed on each of the four first pixels. That is, the first pixel group may include four first pixels, and four first micro lenses may be respectively arranged to respectively correspond to the first pixels. One first micro lens may be disposed per one first pixel. However, this is only an example and embodiments are not limited thereto. First pixels included in the same first pixel group may detect the same color. The first pixel may be referred to as a normal pixel.

The second pixel group may include a plurality of second pixels. The second pixel may be referred to as an AF pixel. An AF pixel may be a pixel that has a circuit or a physical structure for AF. A second micro lens may be disposed on the second pixels. A second micro lens may be disposed on at least two of the second pixels included in the second pixel group. For example, the second pixel group may include a plurality of second pixels, and a second micro lens corresponding to the second pixel group may be disposed. For example, the second pixel group may include four second pixels arranged 2×2. Four second pixels included in the second pixel group may be adjacent to each other, and one second micro lens may be disposed on the four second pixels. One second micro lens may be disposed per four second pixels. However, embodiments are not thereto. Second pixels included in the same second pixel group may detect the same color.

According to an embodiment, the second pixel group may include a plurality of second pixels, and the second pixel group may include sub-pixel groups including at least two adjacent second pixels. A second micro lens may be disposed on the subpixel groups. For example, the second pixel group may include two sub-pixel groups, and each sub-pixel group may include two second pixels. One second micro lens may be disposed on each subpixel group. One second micro lens may be disposed per two second pixels. However, embodiments are not limited thereto.

For example, the number of second pixels included in one second pixel group may be equal to the number of first pixels included in one first pixel group. For example, a first pixel group may include four first pixels, and a second pixel group may include four second pixels. However, embodiments are not limited thereto, and a first pixel group may include 16 first pixels, and a second pixel group may include 16 second pixels. Each of the first pixel group and the second pixel group may include a varying number of pixels.

The first pixel group may output a first image signal generated from all first pixels included in the first pixel. The second pixel group may output a second image signal generated from some second pixels among the second pixels included in the second pixel group. In a period in which the first image signal is output, the second image signal may also be output. When a first image signal is output from the first pixel group, a second image signal may be output from the second pixel group.

In an embodiment, the first image signal and the second image signal may be output in a first sensing readout period included in a readout period. In the first sensing readout period, a first image signal obtained by summing image signals of all first pixels included in the first pixel group may be output. In the first sensing readout period, a second image signal obtained by summing image signals of some of the second pixels included in the second pixel group may be output. For example, a second image signal obtained by summing image signals of second pixels arranged in different adjacent rows and in the same column in the second pixel group may be output. However, embodiments are not limited thereto, and a second image signal obtained by summing image signals of second pixels arranged in different adjacent columns and in the same row in the second pixel group may be output.

The first pixel group may output a third image signal generated from all first pixels included in the first pixel group. The third image signal may be output following the first image signal. The second pixel group may output a fourth image signal generated from all second pixels included in the second pixel group. The fourth image signal may be output following the second image signal. In a period in which the third image signal is output, the fourth image signal may also be output. When the third image signal is output from the first pixel group, the fourth image signal may be output from the second pixel group.

In an embodiment, the third image signal and the fourth image signal may be output from a second sensing readout period included in the readout period. The second sensing readout period may be a period that follows the first sensing readout period. In the second sensing readout period, a third image signal obtained by summing image signals of all first pixels included in the first pixel group may be output. In the second sensing readout period, a fourth image signal obtained by summing image signals of all second pixels included in the second pixel group may be output.

In an embodiment, the first image signal and the third image signal may be used to generate image data to improve an SNR. The first image signal and the third image signal may be image signals output from the first pixel group. In the readout period, the first image signal and the third image signal may be output sequentially. For example, each of the first image signal and the third image signal may include an image signal obtained by summing the image signals of all first pixels included in the first pixel group in one frame, but may include a different or the same noise signal. That is, the first image signal may include a first noise signal, the third image signal may include a second noise signal, and the first noise signal and the second noise signal may be different from each other. SNR image data used to generate an image with an improved SNR may be generated based on the first image signal and the third image signal.

In an embodiment, the first image signal and the third image signal may be used to generate an HDR image. The first pixels may operate with a dual conversion gain. A dual conversion gain includes a low conversion gain (LCG) and a high conversion gain (HCG). Hereinafter, for convenience of description, an operation mode that generates an image signal using an HCG is referred to as an HCG mode, and an operation mode that generates an image signal using an LCG is referred to as an LCG mode. Each of the first pixels may operate in an HCG mode and an LCG mode.

As an example, the first image signal may be an image signal generated from all first pixels included in the first pixel group in an HCG mode. The third image signal may be an image signal generated from all first pixels included in the first pixel group in an LCG mode. In the readout period, the first image signal in an HCG mode and the third image signal in an LCG mode may be sequentially output. HDR image data used to generate an HDR image may be generated based on the first image signal and the third image signal.

In an embodiment, the second image signal and the fourth image signal may be used to generate phase detection data for AF. The second image signal and the fourth image signal may be image signals output from the second pixel group. In the readout period, the second image signal and the fourth image signal may be output sequentially. AF data used for phase difference calculation for an AF function may be generated based on the second image signal and the fourth image signal. Additionally, the fourth image signal may be used to generate images on a frame-by-frame basis.

A color filter may be arranged on each of the plurality of pixels PX to permit light to transmit light in a certain spectrum region, and a color that is to be detected by a pixel may be determined according to a color filter arranged on each of the plurality of pixels PX. However, embodiments are not limited thereto, and the pixel array 110 may include pixels that convert light in spectral regions other than red, green, and blue, into electrical signals. For example, a color filter that passes cyan color light, yellow color light, or magenta color light may be disposed on each of the plurality of pixels PX.

The timing controller 120 may generally control the image sensor 100. The timing controller 120 may control the operation of components included in the image sensor 100. As an example, the timing controller 120 may control the row driver 140 to control operation of pixels included in the pixel array 110. For example, the timing controller 120 may control the row driver 140 such that a pixel PX outputs an image signal in the readout period. The timing controller 120 may generate a control signal. The timing controller 120 may generate control signals RCS for controlling the row driver 140.

The timing controller 120 may control the row driver 140 such that the first image signal is output from the first pixel group and the second image signal is output from the second pixel group in the first sensing readout period. As an example, the timing controller 120 may generate a control signal RCS that controls the row driver 140 such that the first image signal and the second image signal are output in the first sensing readout period.

The timing controller 120 may control the row driver 140 such that the third image signal is output from the first pixel group and the fourth image signal is output from the second pixel group in the second sensing readout period. As an example, the timing controller 120 may generate a control signal RCS that controls the row driver 140 such that the third image signal and the fourth image signal are output in the second sensing readout period.

The row driver 140 may generate a plurality of control signals that are able to control operation of the pixels PX arranged in respective rows under the control by the timing controller 120. The row driver 140 may provide a plurality of control signals respectively to the plurality of pixels PX of the pixel array 110 through the plurality of row lines RL. In response to a plurality of control signals provided from the row driver 140, the pixel array 110 may be driven in units of rows. In this regard, the plurality of pixels PX of the pixel array 110 may sequentially output pixel signals PXS in units of rows. The pixel signal PXS may include a reset signal indicating a reset level of the pixel PX and an image signal generated from the pixel PX.

The row driver 140 may transmit control signals for outputting the pixel signal PXS to the pixel array 110, and the pixel PX may operate in response to the control signals to output the pixel signal PXS. For example, the row driver 140 may generate control signals that control the pixel PX to output the pixel signal PXS in the readout period, and provide the generated control signals to the pixel array 110. The row driver 140 may be controlled such that the first image signal and the second image signal are output in the first sensing readout period, and the third image signal and the fourth image signal are output in the second sensing readout period.

The readout circuit 130 may include the ADC circuit 131 and the data bus 132. A pixel signal PXS may be read out from pixels PX of a row selected by the row driver 140 among the plurality of pixels PX. The pixel signal PXS may include a reset signal or an image signal (or sensing signal). The readout circuit 130 may generate a plurality of pixels values pdt corresponding to the plurality of pixels PX by converting reset signals and image signals received from the pixel array 110 through the plurality of column lines CL into digital signals based on a ramp signal from the ramp signal generator 150.

The readout circuit 130 may output the pixel values pdt based on the pixel signal PXS. In the first sensing readout period, the readout circuit 130 may output a first pixel value based on the first image signal of the first pixel group and output a second pixel value based on the second image signal of the second pixel group. In the second sensing readout period, the readout circuit 130 may output a third pixel value based on the third image signal of the first pixel group and output a fourth pixel value based on the fourth image signal of the second pixel group. In the readout period, the readout circuit 130 may sequentially output the first pixel value and the third pixel value from the first pixel group, and the second pixel value and the fourth pixel value from the second pixel group.

The ADC circuit 131 may include at least one analog-to-digital converter (ADC). For example, the ADC circuit 131 may include a plurality of ADCs respectively corresponding to a plurality of column lines CL. An ADC may compare a reset signal and an image signal received through a corresponding column line CL with a ramp signal and generate a pixel value pdt based on comparison results. For example, the ADC may remove a reset signal from an image signal and generate a pixel value pdt that represents the amount of light detected from the pixel PX. A plurality of pixel values pdt generated in the ADC circuit 131 may be output through the data bus 132.

The ADC circuit 131 may include a plurality of correlated double sampling (CDS) circuits and a plurality of counter circuits. The ADC circuit 131 may convert the pixel signal PXS input from the pixel array 110 into a pixel value pdt, which is a digital signal. Each pixel signal PXS received through each of the plurality of column lines CL is converted into a pixel value pdt, which is a digital signal, by a CDS circuit and a counter circuit.

The CDS circuit may compare the pixel signal PXS received through the column line CL with the ramp signal RAMP and output the comparison result. The CDS circuit may output a comparison signal that transitions from a first level (e.g., logic high) to a second level (e.g., logic low) when the level of the ramp signal RAMP is the same as the level of the pixel signal PXS. The point at which the level of the comparison signal transitions may be determined according to the level of the pixel signal PXS.

The CDS circuit may sample and hold the pixel signal PXS provided from the pixel PX, according to the CDS method, double-sample a level of a certain noise (e.g., a reset signal) and a level according to an image signal, and generate a comparison signal based on a level corresponding to a difference between the levels.

The data bus 132 may temporarily store the pixel value pdt output from the ADC circuit 131 and then output the value. The data bus 132 may include a plurality of column memories and a column decoder. A plurality of pixel values pdt stored in the plurality of column memories may be output to the signal processor 160 inside the image sensor 100 under the control by the column decoder, or may be output to an image signal processor outside the image sensor 100.

The ramp signal generator 150 may generate a ramp signal (e.g., a ramp voltage) of which the level rises or falls at a predetermined slope under the control by the timing controller 120. The ramp signal RAMP may be provided to the readout circuit 130. For example, the ramp signal RAMP may be provided to the ADC circuit 131.

According to an embodiment, the image sensor 100 may further include the signal processor 160. The signal processor 160 may receive pixel values pdt from the readout circuit 130 and perform signal processing on the received pixel values pdt. The signal processor 160 may generate image data IDT by performing signal processing on the pixel values pdt. The image data IDT may include frame-by-frame images, AF data, SNR image data, HDR image data, etc.

The signal processor 160 may generate SNR image data to improve the SNR based on the first pixel value and the third pixel value generated from the first pixel groups. For example, a processor (e.g., the processor 300 of FIG. 1) may generate an image with an improved SNR based on SNR image data. The processor may generate an image with an improved SNR based on an average value of the first pixel value and the third pixel value. However, embodiments are not limited thereto, and the signal processor 160 may be implemented to generate an image with an improved SNR.

In addition, when the pixel PX operates in a dual conversion gain mode including an HCG mode and an LCG mode, the signal processor 160 may generate HDR image data for generating an HDR image, based on the first pixel value and the third pixel value generated from the first pixel groups. For example, the first pixel value may be a pixel value of an HCG mode, the third pixel value may be a pixel value of an LCG mode, and the processor may generate HDR image based on HDR image data. However, embodiments are not limited thereto, and the signal processor 160 may be implemented to generate an HDR image.

The signal processor 160 may generate AF data based on the second pixel value and the fourth pixel value generated from the second pixel groups. For example, the processor may perform an AF operation based on AF data. The signal processor 160 may generate AF data used in phase difference calculation, based on second pixel values generated from at least two pixels arranged in adjacent, different rows and the same column in the second pixel group and fourth pixel values output from all second pixels included in the second pixel group.

Additionally, the signal processor 160 may perform, on the pixel value pdt, noise reduction processing, gain adjustment, waveform normalization processing, interpolation processing, white balance processing, gamma processing, edge emphasis processing, binning, etc. In an embodiment, the signal processor 160 may be provided in a processor outside the image sensor 100 (e.g., the processor 300 of FIG. 1).

FIG. 3 is a diagram illustrating a pixel array according to an embodiment. A pixel array 110a of FIG. 3 may correspond to the pixel array 110 of FIG. 2. Details that overlap with those described above are omitted.

Referring to FIG. 3, the pixel array 110a may include pixel groups PG each including two or more pixels PX that are adjacent to each other. The pixel array 110a may include a first pixel group PXG1 and a second pixel group PXG2. The pixel array 110a may include a structure in which first pixel groups PXG1 and second pixel groups PXG2 are alternately and repeatedly arranged in rows and columns.

Referring to FIG. 3, each pixel group PXG including four pixels PX is illustrated, but is not limited thereto, and each pixel group PXG may have various numbers of pixels PX such as 9 and 16 pixels. For example, the pixel array 110a may include a plurality of pixel groups PXG each including pixels PX arranged in an n×n matrix (n is a positive integer). However, embodiments are not limited to this, and the pixel array 110a may include a plurality of pixel groups PXG each including pixels PX arranged in a 2n×2n matrix (n is a positive integer). In addition, 64 pixels PX are shown as an example in FIG. 3, but this is shown as an example for convenience of description. The number of pixels PX may be determined according to a resolution of the pixel array 110a. Additionally, the image sensor (e.g., the image sensor 100 of FIG. 2) may be applied to the pixel array 100a illustrated in FIG. 3 and a pixel array having a pattern other than those of the first and second micro lenses ML1 and ML2.

The pixel array 110a may include color filters to sense various colors. In an embodiment, the same color filter may be included in units of pixel groups. That is, four pixels PX arranged adjacent to each other in the pixel array 110a may include the same color filter. The same color filter may be arranged on n×n pixels included in each pixel group.

For example, a first pixel group PXG1_1, a first pixel group PXG1_2, a second pixel group PXG2_1, and a second pixel group PXG2_2 may each include one of a green (G) color filter, a red (R) color filter, and a blue (B) color filter. For example, the first pixel group PXG1_1 and the first pixel group PXG1_2 may include a green (G) color filter, the second pixel group PXG2_1 may include a red (R) color filter, and the second pixel group PXG2_2 may include a blue (B) color filter. In an embodiment, the arrangement ratio of the red (R) color filter, the green (G) color filter, and the blue (B) color filter in the pixel array 110a may be 1:2:1.

However, embodiments are not limited thereto, and the first pixel groups PXG1_1 and, PXG1_2 and the second pixel groups PXG2_1 and, PXG2_2 may each include at least one of a white color filter, a yellow color filter, a cyan color filter, and a magenta color filter. Alternatively, the first pixel groups PXG1_1 and, PXG1_2 and the second pixel groups PXG2_1 and, PXG2_2 may each include one of a white color filter, a yellow color filter, a green (G) color filter, a red (R) color filter, and a blue (B) color filter.

A pixel on which the first micro lens ML1 is disposed may be the first pixel PX1, and the first pixel group PXG1 may include first pixels PX1. First micro lenses ML1 respectively corresponding to the first pixels PX1 may be disposed on the first pixels PX1 included in the first pixel group PXG1. As an example, a green (G) filter may be arranged in the first pixel group PXG1. For example, the first pixel group PXG1_1 may include a first green pixel Gr1, a second green pixel Gr2, a third green pixel Gr3, and a fourth green pixel Gr4. The first green pixel Gr1, the second green pixel Gr2, the third green pixel Gr3, and the fourth green pixel Gr4 may be the first pixels PX1. The first micro lenses ML1 may be disposed on the first green pixel Gr1, the second green pixel Gr2, the third green pixel Gr3, and the fourth green pixel Gr4, respectively.

For example, the first pixel group PXG1_2 may include a first green pixel Gb1, a second green pixel Gb2, a third green pixel Gb3, and a fourth green pixel Gb4. The first green pixel Gb1, the second green pixel Gb2, the third green pixel Gb3, and the fourth green pixel Gb4 may be the first pixels PX1. The first micro lenses ML1 may be disposed on the first green pixel Gb1, the second green pixel Gb2, the third green pixel Gb3, and the fourth green pixel Gb4, respectively.

A pixel on which the second micro lens ML2 is disposed may be the second pixel PX2, and the second pixel group PXG2 may include second pixels PX2. The second micro lens ML2 may be disposed on at least two of the second pixels PX2 included in the second pixel group PXG2. For example, the second pixel group PXG2 may include a plurality of second pixels PX2, and a second micro lens ML2 corresponding to the second pixel group PXG2 may be disposed.

In an embodiment, a diameter of the second micro lens ML2 may be greater than a diameter of the first micro lens ML1. Here, a diameter of a micro lens may refer to a length of a longest portion of a widest cross-section of the micro lens. For example, a diameter of the first micro lens ML1 may be r1, and a diameter of the second micro lens ML2 may be r2. r2 may be greater than r1.

A second micro lens ML2 corresponding to the second pixel group PXG2 may be disposed on the second pixel group PXG2. For example, the second pixel group PXG2 may include four second pixels arranged 2×2. Four second pixels PX2 included in the second pixel group PXG2 may be adjacent to each other, and one second micro lens ML2 may be disposed on the four second pixels PX2. However, embodiments are not limited thereto. The first pixel group PXG1_1 may be adjacent to the second pixel group PXG2_1 in a first direction X, and the first pixel group PXG1_1 may be adjacent to the second pixel group PXG2_2 in a second direction Y. Additionally, the first pixel group PXG1_2 may be adjacent to the second pixel group PXG2_2 in the first direction X and may be adjacent to the second pixel group PXG2_1 in the second direction Y. These pixel groups PXG may be repeatedly and alternately arranged within the pixel array 110a.

For example, a red (R) color filter or a blue (B) color filter may be arranged in the second pixel group PXG2. For example, the second pixel group PXG2_1 may include a first red pixel R1, a second red pixel R2, a third red pixel R3, and a fourth red pixel R4. The first red pixel R1, the second red pixel R2, the third red pixel R3, and the fourth red pixel R4 may be the second pixel PX2. A second micro lens ML2 may be disposed on the second pixel group PXG2_1. For example, the second pixel group PXG2_2 may include a first blue pixel B1, a second blue pixel B2, a third blue pixel B3, and a fourth blue pixel B4. The first blue pixel B1, the second blue pixel B2, the third blue pixel B3, and the fourth blue pixel B4 may be the second pixel PX2. A second micro lens ML2 may be disposed on the second pixel group PXG2_2.

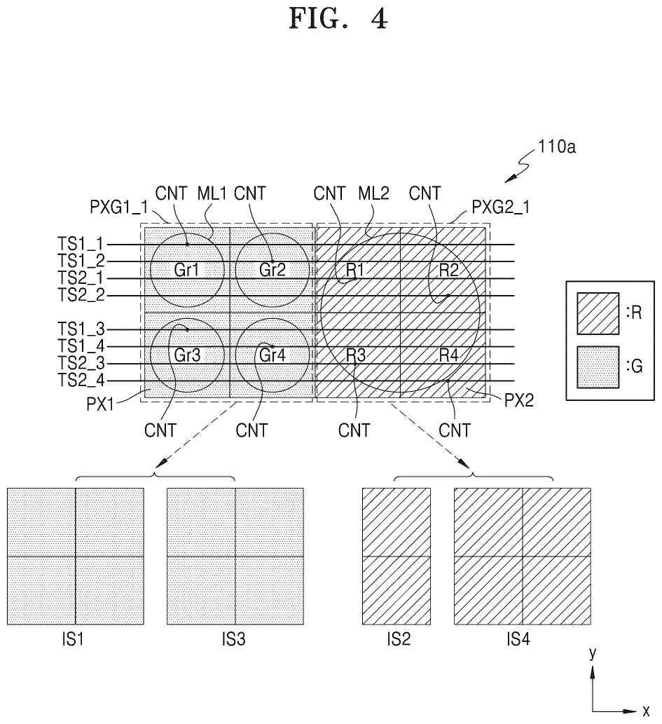

FIG. 4 is a diagram for describing an image signal according to an embodiment. Details that overlap with those described above are omitted.

Referring to FIG. 4, the pixel array 110a may include a first pixel group PXG1_1 and a second pixel group PXG2_1. In FIG. 4, the first pixel group PXG1_1 and the second pixel group PXG2_1 are illustrated for convenience of description, but the details described with reference to FIG. 4 may also be applied to other pixel groups in FIG. 3. Additionally, the above details may be applied to pixel arrays of various patterns and to first pixel groups and second pixel groups included in the pixel arrays.

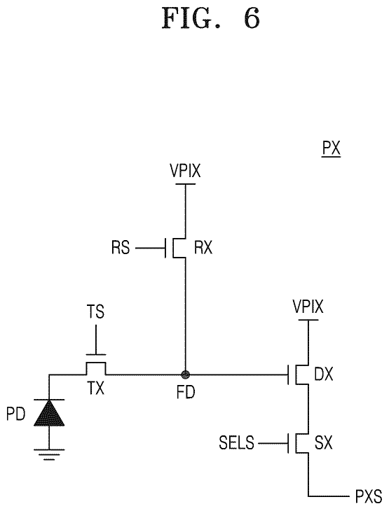

The pixels PX may operate in response to a transmission control signal. For example, the first pixels PX1 included in the first pixel group PXG1_1 may operate in response to a plurality of first transmission control signals TS1_1, TS1_2, TS1_3, and TS1_4, and the second pixels PX2 included in the second pixel group PXG2_1 may operate in response to a plurality of second transmission control signals TS2_1, TS2_2, TS2_3, and TS2_4. Here, the operation of the first pixel PX1 and the second pixel PX2 means that photocharges generated from a photoelectric conversion element included in each of the first pixel PX1 and the second pixel PX2 (for example, a photodiode PD in FIG. 6) are transmitted to a floating diffusion node (FD in FIG. 6) within the pixel PX.

The plurality of first transmission control signals TS1_1, TS1_2, TS1_3, and TS1_4, as well as the plurality of second transmission control signals TS2_1, TS2_2, TS2_3, and TS2_4 may be different signals provided from a row driver (e.g., the row driver 140 in FIG. 2) through different row lines RL. The connection relationship between the row lines RL and the first pixels PX1 and second pixels PX2 is expressed through a connect CNT.

A plurality of rows of the pixel array 110a may be sequentially read in a plurality of readout periods (or multiple horizontal periods). In this regard, a plurality of signals may be read in units of rows from a plurality of pixels PXa. For example, referring to FIGS. 3 and 4 together, in a first readout period, pixel signals may be output from pixel groups PXG arranged in the same row as the first pixel group PXG1_1 and the second pixel group PXG2_1. In a second readout period, a pixel signal may be output from pixel groups PXG arranged in the same row as the second pixel group PXG2_2 and the first pixel group PXG1_2. However, embodiments are not limited thereto, and the order in which a plurality of rows are read out may vary.

The first pixel group PXG1_1 may output a first image signal IS1 generated from all first pixels PX1 included in the first pixel group PXG1_1. For example, image signals respectively generated from the first green pixel Gr1, the second green pixel Gr2, the third green pixel Gr3, and the fourth green pixel Gr4 may be added up and output as the first image signal IS1.

The second pixel group PXG2_1 may output a second image signal IS2 generated from some of the second pixels PX2 included in the second pixel group PXG2_1. For example, the second image signal IS2 may be output from the second pixels PX2 arranged in the same column and in different rows in the second pixel group PXG2_1. For example, image signals respectively generated from the first red pixel R1 and the third red pixel R3 may be added up and output as the second image signal IS2. For example, image signals respectively generated from the second red pixel R2 and the fourth red pixel R4 may not be included when generating the second image signal IS2. A left image signal of the second pixel group PXG2_1 may be the second image signal IS2. However, the second image signal IS2 is not limited thereto, and the second image signal IS2 may be output from the second pixels PX2 arranged in the same row and different columns. In an embodiment, the first image signal IS1 and the second image signal IS2 may be output in the first sensing readout period included in the readout period.

The first pixel group PXG1_1 may output a third image signal IS3 generated from all first pixels PX1 included in the first pixel group PXG1_1. For example, image signals respectively generated from the first green pixel Gr1, the second green pixel Gr2, the third green pixel Gr3, and the fourth green pixel Gr4 may be added up to generate the third image signal IS3. The third image signal IS3 may be output after the first image signal IS1.

The second pixel group PXG2_1 may output a fourth image signal IS4 generated from all second pixels PX2 included in the second pixel group PXG2_1. The fourth image signal IS4 may be output after the second image signal IS2. For example, image signals respectively generated from the first red pixel R1, the second red pixel R2, the third red pixel R3, and the fourth red pixel R4 may be added up and output as the fourth image signal IS4. The third image signal IS3 and the fourth image signal IS4 may be output from the second sensing readout period included in the readout period. The second sensing readout period may be a period that follows the first sensing readout period. In an embodiment, AF data for phase difference calculation for adjustment of a focus in left and right directions may be generated based on the second image signal IS2 and the fourth image signal IS4.

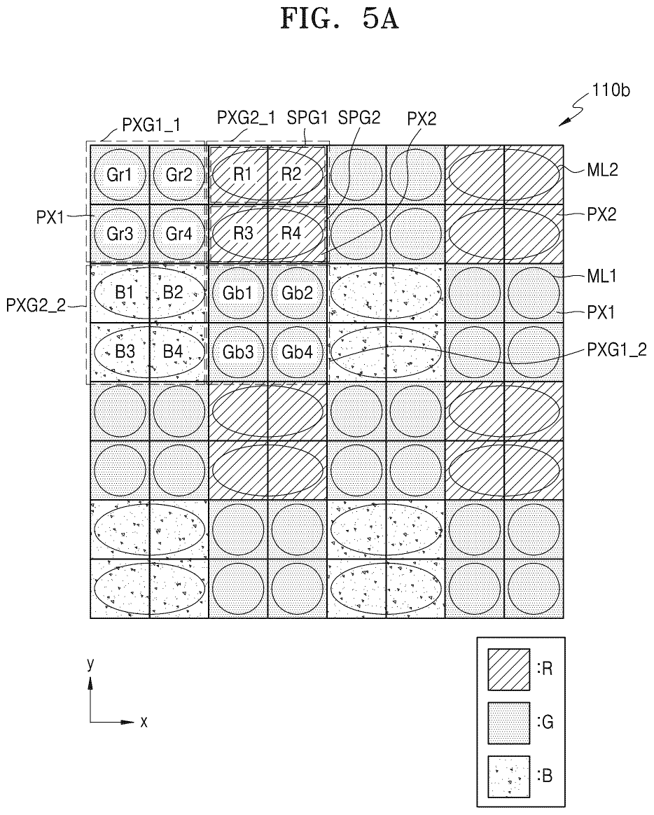

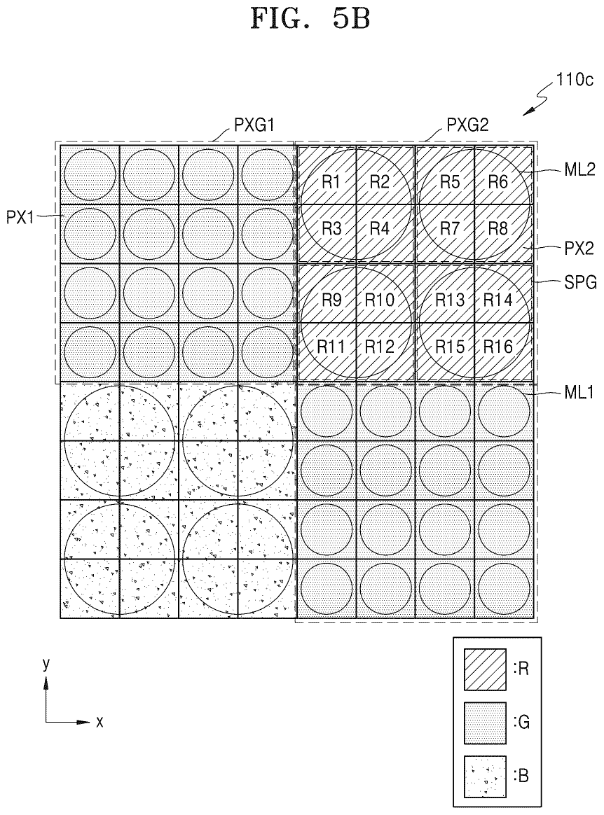

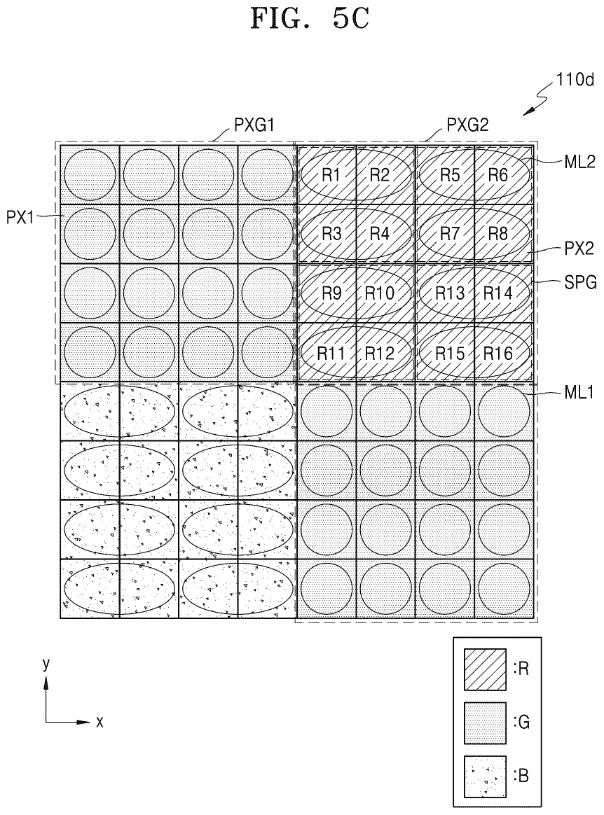

FIG. 5A is a diagram illustrating a pixel array according to an embodiment. A pixel array 110b of FIG. 5A may correspond to the pixel array 110 of FIG. 2. Compared to the pixel array 110a of FIG. 3, two second micro lenses ML2 may be disposed on the second pixel group PXG2 of the pixel array 110b of FIG. 5A. Details that overlap with those described above are omitted.

Referring to FIG. 5A, the pixel array 110b may include a first pixel group PXG1 and a second pixel group PXG2. The pixel array 110b may include a structure in which first pixel groups PXG1 and second pixel groups PXG2 are alternately and repeatedly arranged in rows and columns.

In an embodiment, the second pixel group PXG2 may include a plurality of second pixels PX2, and the second pixel group PXG2 may include sub-pixel groups SPG including at least two adjacent second pixels PX2. A second micro lens ML2 may be disposed on each of the subpixel groups SPG. For example, the second pixel group PXG2_1 may include two sub-pixel groups SPG1, SPG2, and each sub-pixel group SPG1, SPG2 may include two second pixels PX2. A first sub-pixel group SPG1 may include a first red pixel R1 and a second red pixel R2, and a second sub-pixel group SPG2 may include a third red pixel R3 and a fourth red pixel R4. A second micro lens ML2 corresponding to the first subpixel group SPG1 may be disposed on the first subpixel group SPG1, and a second micro lens ML2 corresponding to the second subpixel group SPG2 may be disposed on the second subpixel group SPG2.

In a first sensing readout period, a first image signal may be output from the first pixel group PXG1_1 and a second image signal may be output from the second pixel group PXG2_1. For example, the second image signal IS2 may be output from the second pixel PX2 arranged in the same column and in different row in the second pixel group PXG2_1. For example, image signals generated from each of the first red pixel R1 and the third red pixel R3 may be summed and output as the second image signal IS2.

In a second sensing readout period, a third image signal may be output from the first pixel group PXG1_1 and a fourth image signal may be output from the second pixel group PXG2_1. For example, the image signals generated from each of the first green pixel g1, the second green pixel G2, the third green pixel G3, and the fourth green pixel G4 may be added to form a third image signal IS3 to be output. For example, the image signals generated from each of the first red pixel R1, the second red pixel R2, the third red pixel R3, and the fourth red pixel R4 may be added to form a fourth image signal IS4 to be output.

FIG. 5B is a diagram illustrating a pixel array according to an embodiment. A pixel array 110c of FIG. 3 may correspond to the pixel array 110 of FIG. 2. Compared to the pixel array 110a of FIG. 3, a pixel group PG of the pixel array 110c of FIG. 5B may include 16 pixels. Details that overlap with those described above are omitted.

Referring to FIG. 5B, the pixel array 110c may include a first pixel group PXG1 and a second pixel group PXG2. The pixel array 110c may include a structure in which first pixel groups PXG1 and second pixel groups PXG2 are alternately and repeatedly arranged in rows and columns. Referring to FIG. 5B, each pixel group PXG may include 16 pixels PX, but embodiments are not limited thereto.

The first pixel group PXG1 may include first pixels PX1. For example, the first pixel group PXG1 may include 16 first pixels PX1. For example, the first pixel group PXG1 may include 16 green color first pixels PX1. First micro lenses ML1 respectively corresponding to the first pixels PX1 may be disposed on the first pixels PX1 included in the first pixel group PXG1.

In an embodiment, the second pixel group PXG2 may include a plurality of second pixels PX2, and the second pixel group PXG2 may include sub-pixel groups SPG including at least two adjacent second pixels PX2. Referring to FIG. 5B, the second pixel group PXG2 may include four sub-pixel groups SPG, and each sub-pixel group SPG may include four second pixels PX2.

Second micro lenses ML2 may be disposed on the subpixel groups SPG. For example, the second pixel group PXG2 may include four sub-pixel groups SPG, and each sub-pixel group SPG may include four second pixels PX2. A second micro lens ML2 may be disposed on each of the subpixel groups SPG.

In a first sensing readout period, a first image signal may be output from the first pixel group PXG1_1 and a second image signal may be output from the second pixel group PXG2_1. A first image signal obtained by summing the image signals of the 16 first pixels PX1 included in the first pixel group PXG1_1 may be output. A second image signal obtained by summing the image signals of some of the second pixels PX2 included in the second pixel group PXG2 may be output. For example, the second image signal IS2 may be output from the second pixel PX2 arranged in the same column and in different rows in the second pixel group PXG2_1. For example, an image signal generated from each of the first red pixel R1, the third red pixel R3, the ninth red pixel R9, and the 11th red pixel R11 and an image signal generated from each of the fifth red pixel R5, the seventh red pixel R7, the thirteenth red pixel R13, and the fifteenth red pixel R15 may be summed and output as the second image signal IS2.

In a second sensing readout period, a third image signal may be output from the first pixel group PXG1_1 and a fourth image signal may be output from the second pixel group PXG2_1. A third image signal obtained by summing the image signals of the 16 first pixels PX1 included in the first pixel group PXG1_1 may be output. A fourth image signal obtained by summing the image signals of the 16 second pixels PX2 included in the second pixel group PXG2 may be output.

FIG. 5C is a diagram illustrating a pixel array according to an embodiment. A pixel array 110d of FIG. 5C may correspond to the pixel array 110 of FIG. 2. Compared to the pixel array 110a of FIG. 3, the pixel group PG of the pixel array 110d of FIG. 5C may include 16 pixels. Details that overlap with those described above are omitted.

Referring to FIG. 5C, the second pixel group PXG2 may include a plurality of second pixels PX2, and the second pixel group PXG2 may include sub-pixel groups SPG including at least two adjacent second pixels PX2. The second pixel group PXG2 may include eight sub-pixel groups SPG, and each sub-pixel group SPG may include two second pixels PX2.

A second micro lens ML2 may be disposed on the subpixel groups SPG. For example, the second pixel group PXG2 may include eight sub-pixel groups SPG, and each sub-pixel group SPG may include two second pixels PX2. A second micro lens ML2 may be disposed on each of the subpixel groups SPG. For example, the second micro lens ML2 may be disposed on the sub-pixel group SPG including the first red pixel R1 and the second red pixel R2. In FIG. 5C, the sub-pixel group SPG included in the second pixel group PXG2 and including second pixels PX2 adjacent to each other in the first direction X is illustrated, but is not limited thereto. The sub-pixel group SPG may also include second pixels PX2 that are adjacent to each other in the second direction Y.

In a first sensing readout period, a first image signal may be output from the first pixel group PXG1_1 and a second image signal may be output from the second pixel group PXG2_1. In a second sensing readout period, a third image signal may be output from the first pixel group PXG1_1 and a fourth image signal may be output from the second pixel group PXG2_1.

FIG. 6 is a circuit diagram of a pixel included in the pixel array of FIG. 2. The pixel PX of FIG. 6 may be applied to a first pixel (e.g., the first pixel PX1 in FIG. 3) and a second pixel (e.g., the second pixel PX2 in FIG. 3). For example, a plurality of pixels PX may be included in each of a first pixel group and a second pixel group.

Referring to FIG. 6, one pixel (e.g., one of the first pixel and the second pixel) may include a photoelectric conversion element PD, a transmission transistor TX, a selection transistor SX, a driving transistor DX, and a reset transistor RX. According to an embodiment, at least one of the transmission transistor TX, the selection transistor SX, the driving transistor DX, and the reset transistor RX may be omitted.

A photoelectric conversion element PD may generate photocharges that vary according to the intensity of light. For example, the photoelectric conversion element PD may include a PN junction diode and generate charges in proportion to the amount of incident light, that is, negative electrons and positive holes. Examples of the photoelectric conversion element PD may include at least one of a phototransistor, a photo gate, a pinned photodiode (PPD), and a combination thereof.

The transmission transistor TX may transmit the generated photocharges to the floating diffusion node FD according to a transmission control signal (e.g., one of the transmission control signals TS in FIG. 4). When the transmission transistor TX is turned on, the photocharges generated in the photoelectric conversion element PD may be transmitted to the floating diffusion node FD, and accumulated and stored in the floating diffusion node FD.

The reset transistor RX may periodically reset the charges accumulated in the floating diffusion node FD. A first terminal of the reset transistor RX may be connected to the floating diffusion node FD, and a second terminal of the reset terminal RX may be connected to a power supply voltage VPIX. When the reset transistor RX is turned on according to a reset control signal RS, the power supply voltage VPIX connected to the reset transistor RX may be transmitted to the floating diffusion node FD. When the reset transistor RX is turned on, the charges accumulated in the floating diffusion node FD may be discharged and the floating diffusion node FD may be reset.

The driving transistor DX may be controlled according to the amount of photocharges accumulated in the floating diffusion node FD. The driving transistor DX may include a buffer amplifier and may buffer a signal according to the charges charged in the floating diffusion node FD. The driving transistor DX may amplify a potential change at the floating diffusion node FD and output the same as a pixel signal PXS to a column output line (e.g., one of the column lines CL in FIG. 2).

The selection transistor SX may be connected to the driving transistor DX and, in response to a selection signal SELS, may output a pixel signal PXS to a readout circuit (e.g., the readout circuit 130 in FIG. 2) through the column output line. The control signals (the reset control signal RS, the transmission control signals TS, and the selection signal SELS) included in the pixel PX may be generated from a row driver (e.g., the row driver 140 in FIG. 2).

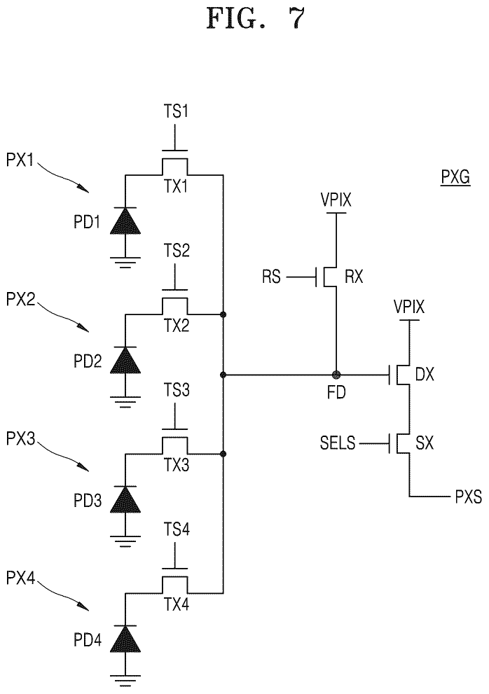

FIG. 7 is a circuit diagram of a pixel included in an image sensor according to an embodiment. According to an embodiment, the pixel group PXG may include a plurality of pixels, and the plurality of pixels PX may share a floating diffusion node FD. For example, a plurality of pixels PX included in one pixel group PXG may share a floating diffusion node FD. In FIG. 7, a case where four pixels share one floating diffusion node FD is shown, but embodiments are not limited thereto, and various numbers of pixels PX may share the floating diffusion node FD.

It is assumed that the pixel group PXG of FIG. 7 corresponds to the pixel group PXG of FIG. 4. Referring to FIGS. 4 and 7, in an embodiment, pixels on which the same color filter is formed and which are arranged adjacent to each other in the first direction X and the second direction Y, for example, the first pixel PX1, the second pixel PX2, the third pixel PX3, and the fourth pixel PX4 may form a pixel group PG sharing the floating diffusion node FD. For example, when the pixel group PXG is the first pixel group PXG1_1, the first pixel PX1, the second pixel PX2, the third pixel PX3, and the fourth pixel PX4 in FIG. 7 may correspond to the first green pixel Gr1, the second green pixel Gr2, the third green pixel Gr3, and the fourth green pixel Gr4 of FIG. 4, respectively. When the pixel group PXG is the second pixel group PXG2_1, the first pixel PX1, the second pixel PX2, the third pixel PX3, and the fourth pixel PX4 in FIG. 7 may correspond to the first red pixel R1, the second red pixel R2, the third red pixel R3, and the fourth red pixel R4 of FIG. 4, respectively.

The pixel group PXG may include a plurality of photoelectric conversion elements PD1 to PD4, a plurality of transmission transistors TX1 to TX4, a selection transistor SX, a driving transistor DX, and a reset transistor RX. In an embodiment, at least one of the selection transistor SX, the driving transistor DX, and the reset transistor RX may be omitted.

Each of the photoelectric conversion elements PD1 to PD4 may generate photocharges that vary according to intensity of light. Each of the transmission transistors TX1 to TX4 may transmit the generated photocharges to the floating diffusion node FD according to the transmission control signal TS. The generated photocharges may be accumulated and stored in the floating diffusion node FD. For example, when the pixel group PXG is the first pixel group PXG1_1, the transmission control signals TS1 to TS4 of FIG. 7 may correspond to the first transmission control signals TS1_1, TS1_2, TS1_3, and TS1_4 of FIG. 4, respectively. When the pixel group PXG is the second pixel group PXG2_1, the transmission control signals TS1 to TS4 of FIG. 7 may correspond to the second transmission control signals TS2_1, TS2_2, TS2_3, and TS2_4 of FIG. 4, respectively.

Each of the first to fourth pixels PX1 to PX4 constituting the pixel group PXG may include a corresponding photoelectric conversion element (for example, one of the photoelectric conversion elements PD1 to PD4) and a corresponding transmission transistor (for example, one of the transmission transistors TX1 to TX4). For example, the first pixel PX1 constituting the pixel group PXG may include a first photoelectric conversion element PD1 and a first transmission transistor TX1, and the second pixel PX2 may include a second photoelectric conversion element PD2 and a second transmission transistor TX2, the third pixel PX3 may include a third photoelectric conversion element PD3 and a third transmission transistor TX3, and the fourth pixel PX4 may include a fourth photoelectric conversion element PD4 and a fourth transmission transistor TX4.

The first to fourth pixels PX1 to PX4 constituting the pixel group PXG may share one floating diffusion node FD. The concept of sharing the pixel group PXG may include not only that a plurality of photoelectric conversion elements (PD1 to PD4) share one floating diffusion node FD, but also the transistors (the reset transistor RX, the driving transistor DX, and the selection transistor SX) (excluding the first to fourth transmission transistors TX1 to TX4. Accordingly, photocharges generated from each of the first to fourth photoelectric conversion elements PD1 to PD4 may be accumulated in the shared floating diffusion node FD.

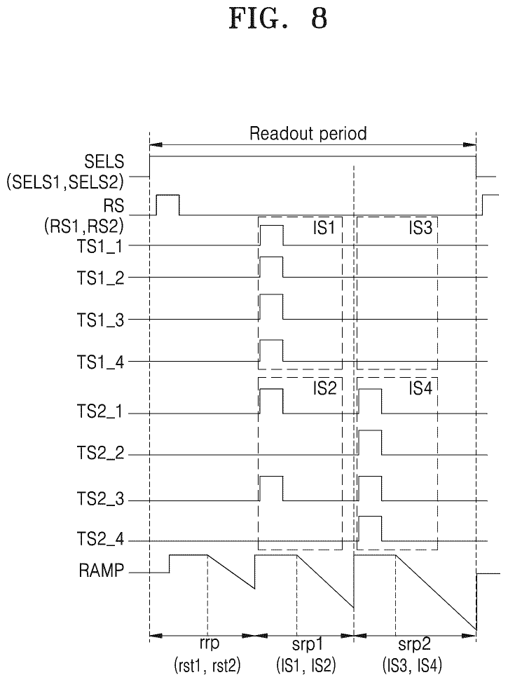

FIG. 8 is a timing diagram of an image sensor for reading a pixel signal according to an embodiment. In FIG. 8, the description will be provided assuming that each of the first pixel group and the second pixel group includes four pixels PX. However, this is for convenience of description, and the description of FIG. 8 may be applied even when each of the first pixel group and the second pixel group includes various numbers of pixels PX. Additionally, the description will be provided assuming that pixels PX included in the pixel group PXG share the floating diffusion node FD. However, embodiments are not limited thereto, and the description of FIG. 8 may be applied similarly even when the pixels PX included in the pixel group PXG do not share the floating diffusion node FD, or the pixels PX that share the floating diffusion node FD may be applied similarly even when the number of the pixels PX that share the floating diffusion node FD is different. Hereinafter, FIGS. 4, 7, and 8 will be referred to together.

In a readout period, a plurality of pixel signals PXS may be read from a plurality of pixels PX arranged in one row of the pixel array (110a in FIG. 4). In the readout period, a pixel signal (e.g., the pixel signal PXS of FIG. 2) may be output from the pixel groups PXG arranged in the same row as the first pixel group PXG1_1, the second pixel group PXG2_1, the first pixel group PXG1_1, and the second pixel group PXG2_1. Pixel signals may be output from the pixel groups PXG, analog-to-digital conversion may be performed on the plurality of pixel signals in a readout circuit (e.g., the readout circuit 130 in FIG. 2), and accordingly, pixel values which are digital values (e.g., the pixel value pdt in FIG. 2) may be generated.

Referring to FIG. 8, the readout period may be divided into a reset readout period rrp, a first sensing readout period srp1, and a second sensing readout period srp2 according to a signal output from the pixel PX and converted analog-to-digital. The first sensing readout period srp1 may follow the reset readout period rrp, and the second sensing readout period srp2 may follow the first sensing readout period srp1.

In the reset readout period rrp, a reset signal rst (e.g., reset voltage) corresponding to the reset level may be output as a pixel signal PXS. In the reset readout period rrp, a reset signal rst may be output from each of the first pixel group PXG1_1 and the second pixel group PXG2_1. In the first sensing readout period srp1, the first image signal IS1 generated from the first pixel group PXG1_1 and the second image signal IS2 generated from the second pixel group PXG2_1 may be output. In the first sensing readout period srp1, the first image signal IS1 may be output as a pixel signal PXS for the first pixel group PXG1_1, and the second image signal IS2 may be output as a pixel signal PXS for the second pixel group PXG2_1. In the second sensing readout period srp2, the third image signal IS3 generated from the first pixel group PXG1_1 and the fourth image signal IS4 generated from the second pixel group PXG2_1 may be output. In the second sensing readout period srp2, the third image signal IS3 may be output as a pixel signal PXS for the first pixel group PXG1_1, and the fourth image signal IS4 may be output as a pixel signal PXS for the second pixel group PXG2_1.

Reset levels of the plurality of pixels PX may vary from each other, and a reset level of one pixel PX may also be different according to time. Thus, in a readout period, the reset signal rst may be first read out from the first pixel PX1, and then the reset signal rst may be subtracted (or added) from (or to) an image signal that is read out later, for example, the first image signal IS1 (or the third image signal IS3). After the reset signal rst is first read out from the second pixel PX2, the reset signal rst may be subtracted (or added) from (or to) the second image signal IS2 (or the fourth image signal IS4). Accordingly, actual image signals may be read out, and signal deviation between image signals output from the plurality of pixels PX may be reduced.

As above, in the readout period, the reset signal rst, the first image signal IS1 (or the second image signal IS2), and the third image signal (IS3) (or the fourth image signal (or IS4)) generated in the pixel PX may be read out sequentially. This readout method may be referred to as a reset-signal-signal (RSS) readout method.

FIG. 8 illustrates operations of transistors included in the first pixel group PXG1_1 and the second pixel group PXG2_1 at one view. For example, when the pixel group PXG of FIG. 7 is the first pixel group PXG1_1, the first to fourth transmission control signals TS1 to TS4 of FIG. 7 may correspond to the first transmission control signals TS1_1, TS1_2, TS1_3, and TS1_4 of FIG. 8, respectively, and the reset control signal RS in FIG. 7 may correspond to the first reset control signal RS1 in FIG. 8, and the selection signal SELS in FIG. 7 may correspond to the first selection signal SELS1 in FIG. 8. For example, when the pixel group PXG of FIG. 7 is the second pixel group PXG2_1, the transmission control signals TS1 to TS4, the reset control signal RS, and the selection signal SELS of FIG. 7 may correspond to the second transmission control signals TS2_1, TS2_2, TS2_3, TS2_4, the second reset control signal RS2, and the second selection signal SELS2 of 8, respectively.

Referring to FIGS. 8, 4, and 7 together, in the readout period, the first selection signal SELS1 may be at an active level, for example, logic high, and the selection transistor SX of the first pixel group PXG1_1 may be turned on in response to the first selection signal SELS1 and the first pixels PX1 may be connected to the column line CL.

In the readout period, the second selection signal SELS2 may be at an active level, for example, logic high, and the selection transistor SX of the second pixel group PXG2_1 may be turned on in response to the second selection signal SELS2 and the second pixels PX2 may be connected to the column line CL. Here, an activation level of a signal refers to a level at which a transistor to which the signal is applied may be turned on. As used herein, logic high is assumed to be an active level and logic low is assumed to be an inactive level.

When the readout period begins, as the first reset control signal RS1 transitions from logic low to logic high, the reset transistor RX of the first pixel group PXG1_1 is turned on and the floating diffusion node FD may be reset. In the reset readout period rrp, the first reset signal rst1 corresponding to a reset level of the floating diffusion node FD of the first pixel group PXG1_1 may be output as the pixel signal PXS through the column line CL. The readout circuit (e.g., the readout circuit 130 in FIG. 2) may compare the ramp signal RAMP with the pixel signal PXS and output a comparison result as a comparison signal. The level of the ramp signal RAMP decreases at a predetermined slope, and when the level of the ramp signal RAMP becomes lower than the level of the pixel signal PXS, the level of the comparison signal may be transitioned. The first reset signal rst1 with respect to the first pixels PX1 included in the first pixel group PXG1_1 may be output in the reset readout period rrp.

As the second reset control signal RS2 of the second pixel group PXG2_1 transitions from logic low to logic high in the reset readout period rrp, the reset transistor RX of the second pixel group PXG2_1 may be turned on to reset the floating diffusion node FD. In the reset readout period rrp, a second reset signal rst2 corresponding to the reset level of the floating diffusion node FD of the second pixel group PXG2_1 may be output as the pixel signal PXS through the column line CL. In the reset readout period rrp, the second reset signal rst2 for the second pixels PX2 included in the second pixel group PXG2_1 may be output.

In the first sensing readout period srp1, the transmission transistors of all first pixels PX1 included in the first pixel group PXG1_1 may be turned on. As the first transmission control signal TS1 transitions to an active level in the first sensing readout period srp1, the charges generated in the first pixels PX1 may be transferred to the floating diffusion node FD of the first pixel group PXG1_1 and stored. Signals generated from all first pixels PX1 included in the first pixel group PXG1_1 may be added up to generate the first image signal IS1. The first image signal IS1 may be output as the pixel signal PXS through the column line CL.

In the first sensing readout period srp1, the transmission transistors of all first pixels PX1 included in the first pixel group PXG1_1 may be turned on. In an embodiment, each of the first transmission control signals TS1_1 to TS1_4 may transition to an active level simultaneously. As an example, the first transmission control signal TS1_1 may transition to an active level in the first sensing readout period srp1, and the charge generated in the first green pixel Gr1 may be transferred to the floating diffusion node FD. In the first sensing readout period srp1, the first transmission control signal TS1_2 may transition to an active level, and the charges generated in the second green pixel Gr2 may be stored in the floating diffusion node FD. In the first sensing readout period srp1, the first transmission control signal TS1_3 may transition to an active level, and the charges generated in the third green pixel Gr3 may be stored in the floating diffusion node FD. In the first sensing readout period srp1, the first transmission control signal TS1_4 may transition to an active level, and the charges generated in the fourth green pixel Gr4 may be stored in the floating diffusion node FD. The charges generated from each of the first green pixel Gr1, the second green pixel Gr2, the third green pixel Gr3, and the fourth green pixel Gr4 of the first pixel group PXG1_1 may be added up and output as the first image signal IS1.

In the first sensing readout period srp1, transmission transistors of some of the second pixels PX21 included in the second pixel group PXG2_1 may be turned on, while transmission transistors of other pixels the second pixels PX21 included in the second pixel group PXG2_1 remain off. As some second transmission control signals TS2 transitions to an active level in the first sensing readout period srp1, charges generated in some of the second pixels PX2 may be transmitted to the floating diffusion node FD of the second pixel group PXG2_1 and stored therein. Signals generated from some second pixels PX2 included in the second pixel group PXG2_1 may be added up to generate a second image signal IS2. The second image signal IS2 may be output as the pixel signal PXS through the column line CL.

For example, the second image signal IS2 may be output from the second pixel PX2 arranged in the same column and in different rows in the second pixel group PXG2_1. In the first sensing readout period srp1, the transmission transistors of some second pixels PX2 included in the second pixel group PXG2_1 may be turned on. In an embodiment, in the first sensing readout period srp1, some of the second transmission control signals TS1_1 to TS1_4 may simultaneously transition to an active level.

For example, in the first sensing readout period srp1, the second transmission control signal TS2_1 may transition to an active level, and the charges generated in the first red pixel R1 may be transferred to the floating diffusion node FD. In the first sensing readout period srp1, the second transmission control signal TS2_3 may transition to an active level, and the charges generated in the third red pixel R3 may be stored in the floating diffusion node FD. Charges generated from each of the first red pixel R1 and the third red pixel R3 of the second pixel group PXG2_1 may be added up and output as the second image signal IS2. In the first sensing readout period srp1, the second transmission control signal TS2_2 and the second transmission control signal TS2_4 may remain at an inactive level, and the charges generated in the second red pixel R2 and the fourth red pixel R4 may not be stored in the floating diffusion node FD. A left image signal of the second pixel group PXG2_1 may be the second image signal IS2. However, the second image signal IS2 is not limited thereto, and the second image signal IS2 may be output from the second pixel PX2 arranged in the same row and different columns.

In the first sensing readout period srp1, the first image signal IS1 and the second image signal IS2 may be output. For example, the first image signal IS1 and the second image signal IS2 may be output simultaneously in the first sensing readout period srp1. However, embodiments are not limited thereto.

In the second sensing readout period srp2, the transmission transistors of all first pixels PX1 included in the first pixel group PXG1_1 may be turned off. In the first sensing readout period srp1, the transmission transistors of the first pixels PX1 included in the first pixel group PXG1_1 may be turned on and then turned off, and in the second sensing readout period srp2, the transmission transistors of all first pixels PX1 included in the first pixel group PXG1_1 may maintain a turned-off state. For example, in the second sensing readout period srp2, all first transmission control signals TS1_1, TS1_2, TS1_3, and TS1_4 may be maintained at an inactive level. With the transmission transistors of the first pixel group PXG1_1 turned off, image signals generated from all first pixels PX1 included in the first pixel group PXG1_1 (i.e., charges currently stored in the floating diffusion node FD of the first pixel group PXG1_1) may be read out once more.

Image signals generated based on the charges stored in the floating diffusion node FD of the first pixel group PXG1_1 in the first sensing readout period srp1 may be read out in the second sensing readout period srp2. Signals generated from all first pixels PX1 included in the first pixel group PXG1_1 may be added up and read out as the third image signal IS3. The third image signal IS3 may be output as a pixel signal PXS through the column line CL.

In the readout period, the first image signal IS1 and the third image signal IS3 may be output sequentially. For example, the first image signal IS1 and the third image signal IS3 may each include an image signal obtained by summing image signals of all first pixels included in a first pixel group in one frame, but include different noise signals. SNR image data used to generate an image with an improved SNR may be generated based on the first image signal IS1 and the third image signal IS3. For example, the SNR image data may be generated based on a difference between the first image signal IS1 and the third image signal IS3.

In the second sensing readout period srp2, the transmission transistors of all second pixels PX2 included in the second pixel group PXG2_1 may be turned on. As the second transmission control signal TS2 transitions to an active level in the second sensing readout period srp2, the charges generated in the second pixels PX2 may be transmitted to and stored in the floating diffusion node FD of the second pixel group PXG2_1. Signals generated from all second pixels PX2 included in the second pixel group PXG2_1 may be added up to generate the fourth image signal IS4. The fourth image signal IS4 may be output as a pixel signal PXS through the column line CL.

For example, in the second sensing readout period srp2, each of the second transmission control signals TS2_1, TS2_2, TS2_3, and TS2_4 may transition to an active level, and charges generated from the first red pixel R1 and the second red pixel R2, the third red pixel R3, and the fourth red pixel R4 may be stored in the floating diffusion node FD. The charges generated from each of the first red pixel R1, second red pixel R2, third red pixel R3, and fourth red pixel R4 of the second pixel group PXG2_1 may be added up and output as the fourth image signal IS4.

In the readout period, the second image signal IS2 and the fourth image signal IS4 may be output sequentially. AF data used for phase difference calculation for an AF function may be generated based on the second image signal IS2 and the fourth image signal IS4. For example, a right image signal of the second pixel group PXG2_1 may be obtained based on the second image signal IS2 and the fourth image signal IS4, and an AF function may be performed based on the second image signal IS2 and the right image signal. Additionally, the fourth image signal may be used to generate images on a frame-by-frame basis.

An image sensor (e.g., the image sensor in FIG. 2) may read out the first image signal IS1 and the second image signal IS2 in the first sensing readout period srp1 and read out the third image signal IS3 and the fourth image signal IS4 in the second sensing readout period srp2, thereby generating an image signal for an AF operation and an image with an improved SNR. The image sensor may improve an SNR and improve image quality while performing an autofocus detection operation.

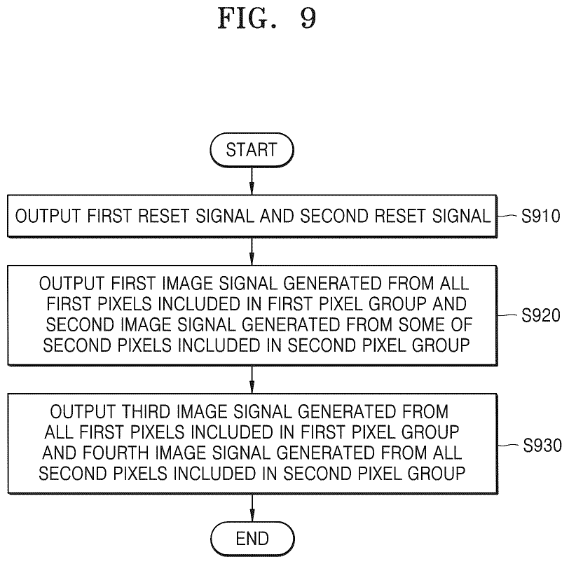

FIG. 9 is a flowchart of a method of operating an image sensor, according to an embodiment. Details that overlap with those described above are omitted. Hereinafter, reference is also made to FIG. 8.

In operation S910, an image sensor (e.g., the image sensor 100 of FIG. 2) may output a first reset signal rst1 and a second reset signal rst2. The readout period may include a reset readout period rrp, and a first reset signal rst1 for first pixels included in a first pixel group may be output in the reset readout period rrp. A second reset signal rst2 for second pixels included in a second pixel group may be output in the reset readout period rrp.

In operation S920, the image sensor may output the first image signal IS1 and the second image signal IS2. The readout period may include a first sensing readout period srp1, and the first sensing readout period srp1 may follow the reset readout period rrp. In the first sensing readout period srp1, signals generated from all first pixels included in the first pixel group may be added up to generate the first image signal IS1.

In the first sensing readout period srp1, signals generated from some second pixels included in the second pixel group may be added up to generate the second image signal IS2. For example, the second image signal IS2 may be output from second pixels arranged in the same column and different rows in the second pixel group. For example, a left image signal of the second pixel group PXG2_1 may be the second image signal IS2. However, the second image signal IS2 is not limited thereto.

In operation S930, the image sensor may output a third image signal and a fourth image signal. The readout period may include a second sensing readout period srp2, and the second sensing readout period srp2 may follow the first sensing readout period srp1. In the second sensing readout period srp2, signals generated from all first pixels included in the first pixel group may be added up to generate the third image signal IS3. In the second sensing readout period srp2, image signals generated from all first pixels included in one pixel group may be read out once more. In the second sensing readout period srp2, signals generated from all second pixels included in the second pixel group may be added up to generate the fourth image signal IS4.

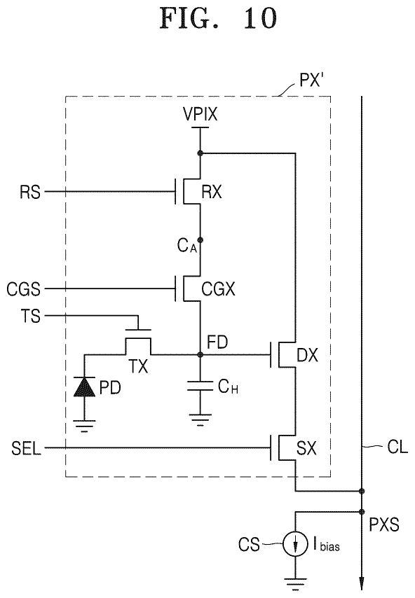

FIG. 10 is a circuit diagram illustrating an implementation example of a pixel according to an embodiment. A pixel PX′ in FIG. 10 may operate with a dual conversion gain. The pixel PX′ of FIG. 10 may be applied to a first pixel (e.g., the first pixel PX1 in FIG. 3) and a second pixel (e.g., the second pixel PX2 in FIG. 3). For example, a plurality of pixels PX′ may be included in each of the first pixel group and the second pixel group. Details that overlaps with those described above with reference to FIG. 6 are omitted.

The pixel PX′ may include a photodiode PD, a plurality of transistors, such as a transmission transistor TX, a reset transistor RX, a driving transistor DX, a selection transistor SX, and a gain control transistor CGX (or a conversion gain control transistor). A capacitor CH, for example, a parasitic capacitor, may be formed by the floating diffusion node FD.

The transmission transistor TX, the reset transistor RX, the driving transistor DX, selection transistor SX, and the gain control transistor CGX may each operate in response to control signals provided from the row driver 140, such as the reset control signal RS, the transmission control signal TS, the selection signal SELS, and the gain control signal CGS.

The charges accumulated in the floating diffusion node FD may generate a voltage. In this regard, the charges accumulated in the floating diffusion node FD may be converted to a voltage. A conversion gain may depend on capacitance of the floating diffusion node FD and may be inversely proportional to the size of the capacitance. As the capacitance of the floating diffusion node FD increases, the conversion gain decreases, and as the capacitance thereof decreases, the conversion gain increases.

The gain control transistor CGX may be turned on or off based on the gain control signal CGS received at a gate terminal thereof, and when the gain control transistor CGX is turned off, the capacitance may be reduced, and when the gain control transistor CGX is turned on, the capacitance may increase. The conversion gain when the gain control transistor CGX is turned off may be higher than the conversion gain when the gain control transistor CGX is turned on. When the gain control transistor CGX is turned off, it may be referred to as an HCG mode, and when the gain control transistor CGX is turned on, it may be referred to as an LCG mode.

The pixel PX′ may operate in either an HCG mode or an LCG mode depending on whether the gain control transistor CGX is on or off. For example, the pixel PX′ may operate in the HCG mode based on the gain control transistor CGX being off, and the pixel PX′ may operate in the LCG mode based on the gain control transistor CGX being on. The pixel PX′ may provide a dual conversion gain DCG to sense light of a low amount and light of a high amount, and a dynamic range of the image sensor (e.g., the image sensor 100 in FIG. 2) may be expanded (or increased).

In an embodiment, when the pixel PX′ operates in a dual conversion gain mode, a timing controller (e.g., the timing controller 120 of FIG. 2) may control a first image signal and a second image signal to be output in a first sensing readout period. The first pixel group may include a plurality of first pixels, and the first pixels may be the pixel PX′ of FIG. 10. However, the pixel PX′ in FIG. 10 is an example, and the structure of the pixel PX′ is not limited thereto. The first image signal may be an image signal obtained by adding up image signals generated from all first pixels included in the first pixel group operating in an HCG mode.

The second pixel group may include a plurality of second pixels, and the second pixels may be the pixel PX′ of FIG. 10. However, embodiments are not limited thereto. The second image signal may be an image signal obtained by summing image signals generated from some second pixels operating in an LCG mode among the second pixels included in the second pixel group.

In an embodiment, when the pixel PX′ operates in a dual conversion gain mode, the timing controller 120 may control a third image signal and a fourth image signal to be output in a second sensing readout period. The second sensing readout period may follow the first sensing readout period. The third image signal may be an image signal obtained by adding up image signals generated from all first pixels included in the first pixel group operating in an LCG mode. The fourth image signal may be an image signal obtained by adding up image signals generated from all second pixels included in the second pixel group operating in an LCG mode.

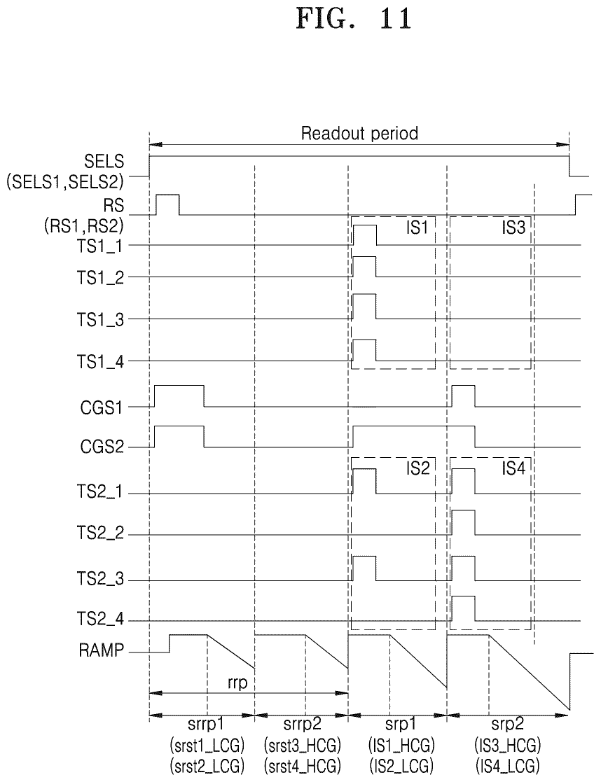

FIG. 11 is a timing diagram of an image sensor for reading a pixel signal, according to an embodiment. In FIG. 11, the description will be provided assuming that each of a first pixel group and a second pixel group includes four pixels PX. However, this is for convenience of description, and the description of FIG. 11 may be applied even when each of the first pixel group and the second pixel group includes various numbers of pixels PX. The pixel PX′ of FIG. 10 may be applied to each of the first pixel and the second pixel. Additionally, the description of FIG. 11 may be similarly applied even when pixels included in a pixel group share a floating diffusion node FD. Details that overlap with those described above are omitted. Hereinafter, FIGS. 10 and 11 will be referred to together.

When the pixel PX′ is a first pixel, the reset transistor RX, the selection transistor SX, and the gain control transistor CGX of each of the first pixels may be controlled based on the first reset control signal RS1, the first selection signal SELS1, and the first gain control signal CGS1. For convenience of description, FIG. 11 shows one first reset control signal RS1, one first selection signal SELS1, and one first gain control signal CGS1, but transistors may be respectively controlled based on the first reset control signal RS1, the first selection signal SELS1, and the first gain control signal CGS1 of each of the first pixels included in the first pixel group. The first pixel group may include four first pixels, and the transmission transistor TX of the four first pixels may be controlled based on each of the first transmission control signals TS1_1, TS1_2, TS1_3, and TS1_4.

When the pixel PX′ is a second pixel, the reset transistor RX, the selection transistor SX, and the gain control transistor CGX of each of the second pixels may be controlled based on the second reset control signal RS2, the second selection signal SELS2, and the second gain control signal CGS2. For convenience of description, FIG. 11 shows one second reset control signal RS2, one second selection signal SELS2, and one second gain control signal CGS2, but transistors may be respectively controlled based on the second reset control signal RS2, the second selection signal SELS2, and the second gain control signal CGS2 of each of the second pixels included in the second pixel group. The second pixel group may include four second pixels, and the transmission transistors TX of the four second pixels may be controlled based on the second transmission control signals TS2_1, TS2_2, TS2_3, and TS2_4, respectively.

Referring to FIGS. 4, 10, and 11 together, in a readout period, a pixel signal (for example, the pixel signal PXS of FIG. 2) may be output from pixel groups PXG arranged in the same row as the first pixel group PXG1_1, the second pixel group PXG2_1, the first pixel group PXG1_1, and the second pixel group PXG2_1.

The readout period may be divided into a reset readout period rrp, a first sensing readout period srp1, and a second sensing readout period srp2. The reset readout period rrp may include a first sub-reset readout period srrp1 and a second sub-reset readout period srrp2. The second sub-reset readout period srrp2 may follow the first sub-reset readout period srrp1. In the readout period, a first sub-reset signal srst1_LCG (or a second sub-reset signal srst2_LCG), a third sub-reset signal srst3_HCG (or a fourth sub-reset signal srst4_HCG), a first image signal IS1_HCG (or a second image signal IS2_LCG), and a third image signal IS3_LCG (or a fourth image signal IS4_LCG) generated from the pixel PX′ may be sequentially read out. This readout method may be referred to as a reset-reset-signal-signal (RRSS) readout method.

In the readout period, the second selection signal SELS2 and the first selection signal SEL1 may be at an active level, for example, logic high. The first sub-reset signal srst1_LCG and the second sub-reset signal srst2_LCG may be output in the first sub-reset readout period srrp1. The first sub-reset signal srst1_LCG may be an LCG mode reset signal output from the first pixel group PXG1_1. The second sub-reset signal srst2_LCG may be an LCG mode reset signal output from the second pixel group PXG2_1.

In the first sub-reset readout period srrp1, the first reset control signal RS1 may transition from logic low to logic high, and the first gain control signal CGS1 may transition from logic low to logic high. In the first sub-reset readout period srrp1, the first sub-reset signal srst1_LCG in an LCG mode for the first pixels PX1 included in the first pixel group PXG1_1 may be output.

In the first sub-reset readout period srrp1, the second reset control signal RS2 may transition from logic low to logic high, and the second gain control signal CGS2 may transition from logic low to logic high. In the first sub-reset readout period srrp1, the second sub-reset signal srst2_LCG in an LCG mode for the second pixels PX2 included in the second pixel group PXG2_1 may be output.

In the second sub-reset readout period srrp2, the third sub-reset signal srst3_HCG and the fourth sub-reset signal srst4_HCG may be read out. The third sub-reset signal srst3_HCG may be a reset signal of an HCG mode, output from the first pixel group PXG1_1. The fourth sub-reset signal srst4_HCG may be a reset signal of an HCG mode, output from the second pixel group PXG2_1.

In the second sub-reset readout period srrp2, the first reset control signal RS1 and the first gain control signal CGS1 may be in a logic low state, and the second reset control signal RS21 and the second gain control signal CGS2 may be in a logic low state. In the second sub-reset readout period srrp2, the third sub-reset signal srst3_HCG in an HCG mode for the first pixels PX1 included in the first pixel group PXG1_1 may be output. In addition, in the second sub-reset readout period srrp2, the fourth sub-reset signal srst4_HCG in an HCG mode for the second pixels PX2 included in the second pixel group PXG2_1 may be output.

In the first sensing readout period srp1, the first image signal IS1_HCG may be output from the first pixel group PXG1_1, and the second image signal IS2_LCG may be output from the second pixel group PXG2_1. In the first sensing readout period srp1, the transmission transistors of all first pixels PX1 included in the first pixel group PXG1_1 may be turned on. In the first sensing readout period srp1, the first transmission control signals TS1_1, TS1_2, TS1_3, and TS1_4 may transition to an active level, and the first gain control signal CGS1 may be in a logic low state. In the first sensing readout period srp1, the first pixels may operate in an HCG mode. Signals generated from all first pixels PX1 included in the first pixel group PXG1_1 may be added up to generate the first image signal IS1_HCG.

In the first sensing readout period srp1, the transmission transistors of each of some of the second pixels PX2 included in the second pixel group PXG2_1 may be turned on. In the first sensing readout period srp1, some of the second transmission control signals TS2_1 and TS2_3 may transition to an active level, and the second gain control signal CGS2 may transition from logic low to logic high. In the first sensing readout period srp1, the second pixels PX2 may operate in an LCG mode. Signals generated from some of the second pixels PX2 included in the second pixel group PXG2_1 may be added up and output as the second image signal IS2_LCG.

In the second sensing readout period srp2, the third image signal IS3_LCG may be output from the first pixel group PXG1_1, and the fourth image signal IS4_LCG may be output from the second pixel group PXG2_1. In the second sensing readout period srp2, the transmission transistors of all first pixels PX1 included in the first pixel group PXG1_1 may be maintained in a turned-off state. In the second sensing readout period srp2, the first transmission control signals TS1_1, TS1_2, TS1_3, and TS1_4 may be in a logic low state, and the first gain control signal CGS1 may transition from logic low to logic high. Because the first gain control signal CGS1 is at an active level in the second sensing readout period srp2, the first pixels PX1 may operate in an LCG mode. Signals generated from all first pixels PX1 included in the first pixel group PXG1_1 may be added up to generate the third image signal IS3_LCG.

In the second sensing readout period srp2, the transmission transistors of all second pixels PX2 included in the second pixel group PXG2_1 may be turned on. In the second sensing readout period srp2, the second transmission control signals TS2_1, TS2_2, TS2_3, TS2_4 may transition from logic low to logic high, and the second gain control signal CGS2 may be maintained in a logic high state. Because the second gain control signal CGS2 is at an active level in the second sensing readout period srp2, the second pixels PX2 may operate in an LCG mode. Signals generated from all second pixels PX2 included in the second pixel group PXG2_1 may be added up to generate the fourth image signal IS4_LCG.

In the readout period, the first image signal IS1_HCG and the third image signal IS3_LCG may be output sequentially. The second image signal IS2_LCG and the fourth image signal IS4_LCG may be output sequentially. Image data used to generate an HDR image for the first pixel group PXG1_1 may be generated based on the first image signal IS1_HCG and the third image signal IS3_LCG. Additionally, image data used to generate an HDR image for the second pixel group PXG2_1 may be generated based on the fourth image signal IS4_LCG.

The image sensor (e.g., the image sensor in FIG. 2) may read out the first image signal IS1_HCG and the second image signal IS2_LCG from the first sensing readout period srp1 and read out the third image signal IS3_LCG and the fourth image signal IS4_LCG from the second sensing readout period srp2, thereby generating together image signals for an AF operation and generating an HDR image. The image sensor may perform an HDR operation and improve image quality while performing autofocus detection operations.

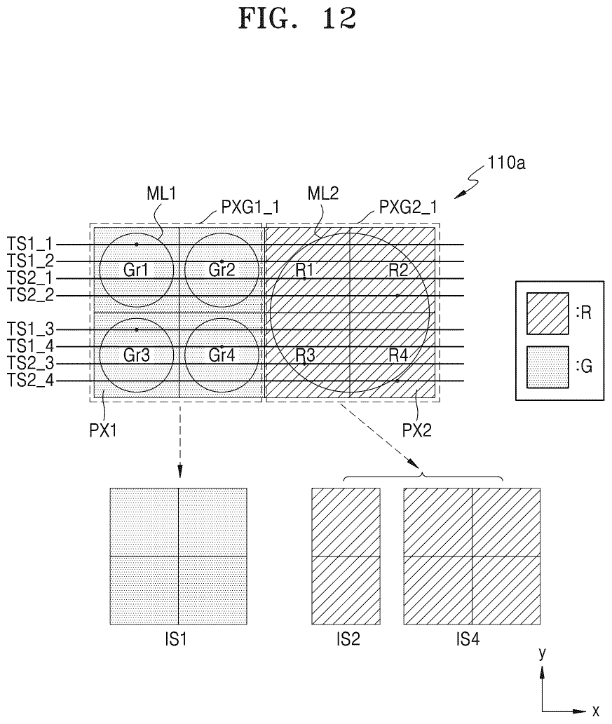

FIG. 12 is a diagram for describing an image signal of a first pixel group, according to an embodiment. Details that overlaps with those described above with reference to FIG. 4 are omitted.

Referring to FIG. 12, an image signal may be read out once from the first pixel group PXG1_1 in the readout period.

In the first sensing readout period, the first pixel group PXG1_1 may output the first image signal IS1 generated from all first pixels PX1 included in the first pixel group PXG1_1, and the second pixel PXG2_1 may output the second image signal IS2 generated from some of the second pixels PX2 included in the second pixel group PXG2_1.

In the second sensing readout period, no image signal may be read out from the first pixel group PXG1_1, and the fourth image signal IS4 generated from all second pixels PX2 included in the second pixel group PXG2_1 may be read out from the second pixel group PXG2_1.

However, embodiments are not limited thereto, and in the first sensing readout period, no image signal may be read out from the first pixel group PXG1_1, and the second image signal IS2 generated from some of the second pixels PX2 included in the second pixel group PXG2_1 may be read out from the second pixel group PXG2_1. In the second sensing readout period, the first image signal IS1 generated from all first pixels PX1 included in the first pixel group PXG1_1 may be read out from the first pixel group PXG1_1, and the fourth image signal IS4 generated from all second pixels PX2 included in the second pixel group PXG2_1 may be read out from the second pixel group PXG2_1.

The image sensor (e.g., the image sensor 10 in FIG. 2) may read out the first image signal IS1 from the first pixel group PXG1_1 in one of the first sensing readout period and the second sensing readout period, the second image signal IS2 from the second pixel group PXG2_1 in the first sensing readout period, and the fourth image signal IS4 from the second pixel group PXG2_1 in the second sensing readout period. The image sensor may read out an image signal obtained by summing up from each of the first pixels included in the first pixel group PXG1_1 once in the readout period, thereby reducing power consumption.

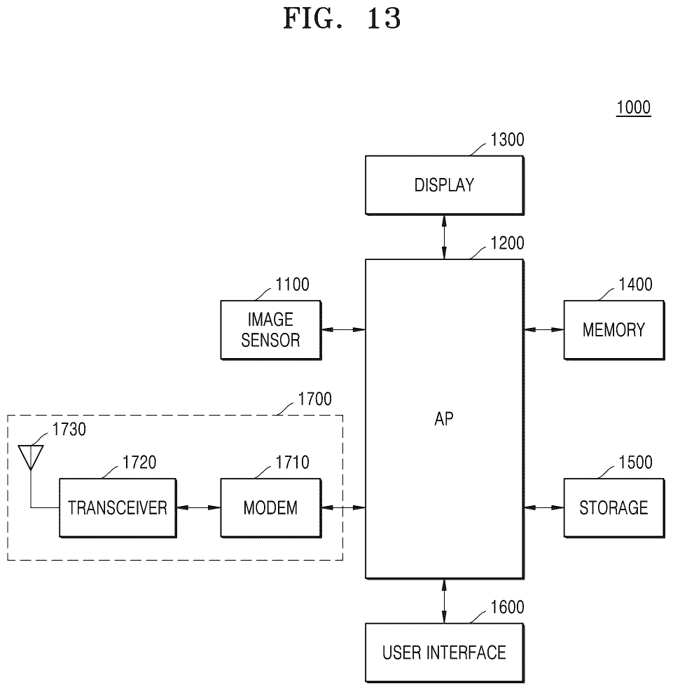

FIG. 13 is a block diagram illustrating an electronic device according to an embodiment. For example, an electronic device 1000 may be a portable terminal.

Referring to FIG. 13, the electronic device 1000 according to an embodiment may include an application processor 1200, an image sensor 1100, a display 1300, a memory 1400, a storage 1500, a user interface 1600, and a wireless transceiver 1700. The description of the image sensor and the method of operating the image sensor according to embodiments described with reference to FIGS. 1 to 12 may be applied to the image sensor 1100.

The image sensor 1100 may generate image data based on a received optical signal and provide the image data to the application processor 1200. The image data may include AF data, SNR image data, HDR image data, etc.

The image sensor 1100 may read out, in a first sensing readout period for one frame, a first image signal from all first pixels included in a first pixel group and a second image signal generated from some of second pixels included in a second pixel group. In the first sensing readout period, the number of transmission transistors of the first pixels, which are turned on and the number of transmission transistors of the second pixels that are turned on may be different. For example, in the first sensing readout period, the transmission transistor of each of the four first pixels may be turned on, and the transmission transistor of each of the two second pixels of the four second pixels may be turned on while the transmission transistor of two other of the second pixels of the four second pixels may be turned off. In a second sensing readout period following the first sensing readout period, the image sensor 1100 may read out a third image signal generated from all first pixels included in the first pixel group and a fourth image signal generated from all second pixels included in the second pixel group. An AF operation may be performed based on the second image signal and the fourth image signal.

The application processor 1200 may control the overall operation of the electronic device 1000 and may be provided as a system-on-chip (SoC) that runs an application program, operating system, etc.

The application processor 1200 may receive output data from the image sensor 1100.

The memory 1400 may be implemented as volatile memory such as dynamic random access memory (DRAM) or static random access memory (SRAM), or non-volatile resistive memory such as ferroelectric random access memory (FeRAM), resistive random access memory (RRAM), or phase-change random access memory (PRAM). The memory 1400 may store programs and/or data that the application processor 1200 processes or executes.

The storage 1500 may be implemented as a non-volatile memory device such as NAND flash or resistive memory. For example, the storage 1500 may be provided as a memory card (multimedia card (MMC), embedded MMC (eMMC), secure digital (SD), micro SD), etc. The storage 1500 may store data and/or programs for an execution algorithm that controls an image processing operation of the image sensor 1100, and the data and/or program may be loaded into the memory 1400 when the image processing operation is performed. In an embodiment, the storage 1500 may store output image data generated by the image sensor 1100, for example, corrected image data or post-processed image data.

The user interface 1600 may be implemented with various devices capable of receiving a user input, such as a keyboard, curtain key panel, touch panel, fingerprint sensor, and microphone. The user interface 1600 may receive a user input and provide a signal corresponding to the received user input to the application processor 1200.

The wireless transceiver 1700 may include a transceiver 1720, a modem 1710, and an antenna 1730.

While aspects of embodiments have been particularly shown and described, it will be understood that various changes in form and details may be made therein without departing from the spirit and scope of the following claims.

What is claimed is:

1. An image sensor comprising:
a first pixel group comprising a plurality of first pixels, wherein a plurality of first micro lenses are on the plurality of first pixels, respectively;
a second pixel group comprising a plurality of second pixels, wherein a second micro lens is on at least two of the plurality of second pixels; and
a timing controller configured to:
control, in a first sensing readout period of a readout period, a first image signal generated from each of the plurality of first pixels and a second image signal generated from a first portion of the plurality of second pixels to be output, and
control, in a second sensing readout period of the readout period that follows the first sensing readout period, a third image signal generated from each of the plurality of first pixels and a fourth image signal generated from each of the plurality of second pixels to be output.

2. The image sensor of claim 1, wherein each of the plurality of first pixels and each of the plurality of second pixels comprises:
a photoelectric conversion element configured to generate photocharges based on incident light; and
a transmission transistor configured to transmit the photocharges generated by the photoelectric conversion element to a floating diffusion node, and
wherein in the first sensing readout period, the transmission transistor of each of the plurality of first pixels is turned on, and wherein the transmission transistor of each of the first portion of the plurality of second pixels is turned on, and the transmission transistor of each of a second portion of the plurality of second pixels is turned off.

3. The image sensor of claim 2, wherein the second sensing readout period, the transmission transistor of each of the plurality of first pixels is turned off, and the transmission transistor of each of the plurality of second pixels is turned on.

4. The image sensor of claim 1, wherein the readout period further comprises a reset readout period preceding the first sensing readout period, and
wherein the timing controller is further configured to control, in the reset readout period, a first reset signal for the plurality of first pixels to be output and a second reset signal for the plurality of second pixels to be output.

5. The image sensor of claim 1, wherein the timing controller is further configured to generate phase detection data for auto-focusing based on the second image signal and the fourth image signal.

6. The image sensor of claim 1, wherein the timing controller is further configured to generate image data for improving a signal to noise ratio (SNR) based on the first image signal and the third image signal.

7. The image sensor of claim 1, wherein the timing controller is further configured to control, in the first sensing readout period, the first image signal and the second image signal to be output, the first image signal being generated from each of the plurality of first pixels while operating in a high conversion gain (HCG) mode and the second image signal being generated from the first portion of the plurality of second pixels while operating in a low conversion gain (LCG) mode.

8. The image sensor of claim 7, wherein the timing controller is further configured to control, in the second sensing readout period, the third image signal and the fourth image signal to be output, the third image signal being generated from each of the plurality of first pixels while operating in the LCG mode and the fourth image signal being generated from all second pixels in the second pixel group while operating in the LCG mode.

9. The image sensor of claim 8, wherein the readout period further comprises a first sub-reset readout period and a second sub-reset readout period following the first sub-reset readout period and preceding the first sensing readout period, and
wherein the timing controller is further configured to:
control, in the first sub-reset readout period, a first sub-reset signal for the plurality of first pixels operating in the LCG mode and a second sub-reset signal for the plurality of second pixels operating in the LCG mode to be output, and
control, in the second sub-reset readout period, a third sub-reset signal for the plurality of first pixels operating in the HCG mode and a fourth sub-reset signal for the plurality of second pixels operating in the LCG mode to be output.

10. The image sensor of claim 8, wherein the timing controller is further configured to generate image data for a high dynamic range (HDR) image for the first pixel group based on the first image signal and the third image signal.

11. The image sensor of claim 1, wherein the plurality of first pixels comprises four first pixels, and the plurality of first micro lenses comprises four first micro lenses,
wherein the first portion of the plurality of second pixels comprises two adjacent second pixels,
wherein the plurality of second pixels comprises four second pixels, and the second micro lens extends across the four second pixels, and
wherein the timing controller is further configured to:
control, in the first sensing readout period, the first image signal the be obtained by summing respective image signals of the four first pixels and the second image signal to be obtained by summing image signals of the two adjacent second pixels, and
control, in the second sensing readout period, the third image signal to be obtained by summing respective image signals of the four first pixels and the fourth image signal to be obtained by summing respective image signals of the four second pixels.

12. The image sensor of claim 1, wherein the plurality of first pixels comprises four first pixels, and the plurality of first micro lenses comprises four first micro lenses,
wherein the first portion of the plurality of second pixels comprises four second pixels divided into two sub-pixel groups, each of the two sub-pixel groups comprising two adjacent second pixels, and the second micro lens extends across each of the two sub-pixel groups, and
wherein the timing controller is further configured to:
control, in the first sensing readout period, the first image signal to be obtained by summing respective image signals of the four first pixels and the second image signal to be obtained by summing respective image signals of some second pixels in each of the two sub-pixel groups, and
control, in the second sensing readout period, the third image signal to be obtained by summing respective image signals of the four first pixels and the fourth image signal to be obtained by summing respective image signals of the four second pixels to be output.

13. An image sensor comprising:
a first pixel group comprising a plurality of first pixels arranged in rows and columns;
a second pixel group comprising a plurality of second pixels arranged in rows and columns;
a plurality of first micro lenses on the plurality of first pixels, respectively;
a second micro lens on at least two of the plurality of second pixels, the second micro lens having a diameter greater than that of a first micro lens of the plurality of first micro lenses; and
a readout circuit configured to:
sequentially output, in a readout period, a first pixel value generated based on each of the plurality of first pixels and a third pixel value generated based on each of the plurality of first pixels, and
sequentially output, in the readout period, a second pixel value generated based on a first portion of the plurality of second pixels among the plurality of second pixels and a fourth pixel value generated based on each of the plurality of second pixels.

14. The image sensor of claim 13, wherein the readout circuit is further configured to, in a first sensing readout period in the readout period, output the first pixel value and the second pixel value.

15. The image sensor of claim 13, wherein each of the plurality of first pixels and each of the plurality of second pixels comprises:
a photoelectric conversion element configured to generate photocharges based on incident light; and
a transmission transistor configured to transmit the photocharges generated by the photoelectric conversion element to a floating diffusion node, and
wherein in the readout period, the transmission transistor of each of the plurality of first pixels is turned on and then turned off, and after the transmission transistor of each of the first portion of the plurality of second pixels is turned on, the transmission transistor of each of the plurality of second pixels is turned on.

16. The image sensor of claim 13, wherein auto-focusing data is generated based on the second pixel value and the fourth pixel value.

17. The image sensor of claim 13, wherein the first pixel value comprises a pixel value generated based on the plurality of first pixels operating in a high conversion gain (HCG) mode in the readout period, and
wherein the third pixel value comprises a pixel value generated based on the plurality of first pixels operating in a low conversion gain (LCG) mode in the readout period.

18. The image sensor of claim 13, wherein the second pixel value comprises a pixel value generated based on the first portion of the plurality of second pixels operating in a low conversion gain (LCG) mode in the readout period, and
wherein the fourth pixel value comprises a pixel value generated based on each of the plurality of second pixels operating in the LCG mode in the readout period.

19. The image sensor of claim 13, wherein the plurality of first pixels comprises four first pixels, and the plurality of first micro lenses comprises four first micro lenses, and
wherein the plurality of second pixels comprises four second pixels, and the second micro lens extends across the four second pixels.

20. An operating method of an image sensor, the image sensor comprising a first pixel group comprising first pixels, a second pixel group including second pixels, first micro lenses disposed on the first pixels, respectively, and a second micro lens disposed on at least two of the second pixels, the operating method comprising:
outputting a first reset signal for the first pixels and a second reset signal for the second pixels;
outputting a first image signal generated from each of the first pixels and a second image signal generated from a first portion of the second pixels; and
outputting a third image signal generated from the of the first pixels and a fourth image signal from each of the second pixels.
